(19) United States
(12) Patent Application Publication
(10) Pub. No.: US 2013/0069151 A1
(43) Pub. Date: Mar. 21, 2013

(54) SEMICONDUCTOR DEVICE

(71) Applicants: TSUYOSHI OHTA, KANAGAWA-KEN (JP); SHINICHIRO MISU, TOKYO (JP); MASATOSHI ARAI, TOKYO (JP)

(72) Inventors: TSUYOSHI OHTA, KANAGAWA-KEN (JP); SHINICHIRO MISU, TOKYO (JP); MASATOSHI ARAI, TOKYO (JP)

(73) Assignee: KABUSHIKI KAISHA TOSHIBA, TOKYO (JP)

(21) Appl. No.: 13/424,347

(22) Filed: Mar. 19, 2012

(30) Foreign Application Priority Data
Sep. 21, 2011 (JP) 2011-206645

(51) Int. Cl. H01L 29/78

(52) U.S. Cl. 257/331; 257/E29.262

(57) ABSTRACT

According to one embodiment, a semiconductor device includes: a substrate; a first conductive portion extending in a first direction perpendicular to a major surface of the substrate; a second conductive portion extending in the first direction; a semiconductor portion provided between the first and the second conductive portions and including a first semiconductor region; a first electrode portion extending in the first direction between the first and the second conductive portions; a second electrode portion extending in the first direction between the first and the second conductive portions; a first insulting portion provided between the first electrode portion and the semiconductor portion and having a first thickness; and a second insulating portion provided between the second electrode portion and the semiconductor portion and having a second thickness greater than the first thickness.

### CROSS-REFERENCE TO RELATED APPLICATIONS

This application is based upon and claims the benefit of priority from the prior Japanese Patent Application No. 2011-206645, filed on Sep. 21, 2011; the entire contents of which are incorporated herein by reference.

### FIELD

Embodiments described herein relate generally to a semiconductor device.

### BACKGROUND

There is a semiconductor device having a structure in which a gate electrode of a metal oxide semiconductor field effect transistor (MOSFET), an anode electrode of a Schottky barrier diode and the like are extended in a direction of a major surface of and in a direction of the depth of a semiconductor region. In this semiconductor device, since a substantial operating region extends in the direction of the major surface and in the direction of the depth, it is possible to achieve the reduction of an on-resistance. In contrast, the thickness of the gate electrode is constant, and, when the thickness of a gate insulting film for obtaining a desired Vth (a gate on voltage) is decreased, it is likely that the breakdown voltage is reduced and that the capacity is increased. In this type of semiconductor device, it is desirable to further enhance breakdown voltage and reduce the capacity.

### BRIEF DESCRIPTION OF THE DRAWINGS

FIG. 1 is a schematic perspective view illustrating the configuration of a semiconductor device according to a first embodiment;

FIGS. 2A and 2B are schematic views illustrating a cross section and an electric field strength distribution;

FIGS. 3A to 8 are schematic perspective views illustrating the method of manufacturing the semiconductor device;

FIGS. 9A to 17B are diagrams illustrating the variations of the structure within the trench;

FIGS. 18A to 18J show schematic plan views of the Z1 portion shown in FIG. 1 in order of the processes;

FIGS. 19A to 19F are schematic views illustrating the method (a second method) of manufacturing the structure within the trench;

FIGS. 20A to 20I show schematic plan views of the Z1 portion shown in FIG. 1 in order of the processes;

FIGS. 21A to 21F are schematic views illustrating the method (a fourth method) of manufacturing the structure within the trench;

FIGS. 22A to 22F are schematic views illustrating the method (a fifth method) of manufacturing the structure within the trench.

FIGS. 23A to 23E are schematic views illustrating the method (a sixth method) of manufacturing the structure within the trench;

FIGS. 24A to 24F are schematic views illustrating the method (a seventh method) of manufacturing the structure within the trench;

FIGS. 25A to 25G are schematic views illustrating the method (an eighth method) of manufacturing the structure within the trench;

FIG. 26 is a schematic perspective view illustrating the configuration of a semiconductor device according to a second embodiment;

FIGS. 27A and 27B are schematic views illustrating a cross section and an electric field strength distribution;

FIGS. 28 to 30 are schematic perspective views illustrating the method of manufacturing the semiconductor device;

FIGS. 31A to 32B are diagrams illustrating the variations of the semiconductor device;

FIG. 33 is a schematic perspective view illustrating another example of the second electrode portion;

FIG. 34 is a schematic perspective view illustrating another example of the first insulating portion;

FIG. 35 is a schematic perspective view illustrating the configuration of a semiconductor device according to a third embodiment;

FIGS. 36A to 42B are diagrams illustrating variations of the structure within the trench;

FIGS. 43A to 43F are schematic views illustrating the method (a first method) of manufacturing the structure within the trench having divided trenches;

FIGS. 44A to 44F are schematic views illustrating the method (a second method) of manufacturing the structure within the trench having divided trenches;

FIG. 45 is a schematic perspective view illustrating the configuration of a semiconductor device according to a fourth embodiment;

FIG. 46 is a schematic plan view illustrating the configuration of the semiconductor device according to the fourth embodiment;

FIGS. 47 to 49 are schematic plan views illustrating other structures of the semiconductor device according to the fourth embodiment;

FIG. 50 is a schematic perspective view illustrating another electric field alleviation region; and

FIG. 51 is a schematic perspective view showing the reference example.

### DETAILED DESCRIPTION

In general, according to one embodiment, a semiconductor device includes: a substrate; a first conductive portion extending in a first direction perpendicular to a major surface of the substrate; a second conductive portion extending in the first direction and provided to be separated from the first conductive portion along a second direction perpendicular to the first direction; a semiconductor portion provided between the first conductive portion and the second conductive portion and including a first semiconductor region of a first impurity concentration and of a first conductive form; a first electrode portion extending in the first direction between the first conductive portion and the second conductive portion; a second electrode portion extending in the first direction between the first conductive portion and the second conductive portion and provided to be separated from the first electrode portion; a first insulting portion provided between the first electrode portion and the semiconductor portion and having a first thickness in a normal direction of a boundary face of the first electrode portion; and a second insulating portion provided between the second electrode portion and the semiconductor portion and having a second thickness greater than the first thickness in a normal direction of a boundary face of the second electrode portion.

Embodiments of the invention will now be described with reference to the drawings.

The drawings are schematic or conceptual; and the relationships between the thicknesses and widths of portions, the proportions of sizes among portions, etc., are not necessarily the same as the actual values thereof. Further, the dimensions and the proportions may be illustrated differently among the drawings, even for identical portions.

In the specification and the drawings of the application, components similar to those described in regard to a drawing thereinabove are marked with like reference numerals, and a detailed description is omitted as appropriate.

In the embodiments, as an example, a specific example is taken where a first conductive type is assumed to be the n-type and a second conductive type is assumed to be the p-type.

The representation of n⁺, n, n⁻ and p⁺, p, p⁻ indicates the relative magnitude of an impurity concentration in the individual conductive types. That is, the representation indicates that n⁺is relatively higher in the n-type impurity concentration than n, and n⁻ is relatively lower in the n-type impurity concentration than n. The representation also indicates that p⁺ is relatively higher in the p-type impurity concentration than p, and p⁻ is relatively lower in the p-type impurity concentration than p.

In the embodiments, a description will be given using a XYZ coordinate system.

### First Embodiment

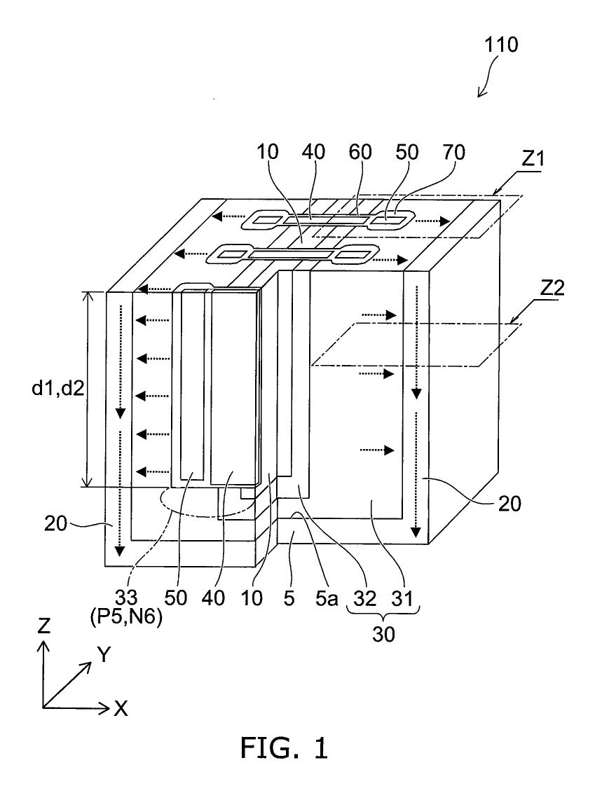

FIG. 1 is a schematic perspective view illustrating the configuration of a semiconductor device according to a first embodiment.

In FIG. 1, by referring to a direction perpendicular to a major surface 5a of a substrate 5 as a Z-axis direction (a first direction) and directions perpendicular to the Z-axis direction as an X-axis direction (a second direction) and a Y-axis direction (a third direction), FIG. 1 shows a partially exploded schematic perspective view of a semiconductor device 110. The semiconductor device 110 shown in FIG. 1 is a MOSFET. In FIG. 1, for ease of description, only part of the semiconductor device 110 is shown.

The semiconductor device 110 includes the substrate 5, a first conductive portion 10, a second conductive portion 20, a semiconductor portion 30, a first electrode portion 40, a second electrode portion 50, a first insulating portion 60 and a second insulating portion 70.

In the semiconductor device 110, as the substrate 5, for example, an n⁺ semiconductor substrate is used. The semiconductor substrate is, for example, a silicon wafer.

On the substrate 5, the first conductive portion 10 is provided so as to extend in the Z-axis direction. In the semiconductor device 110 shown in FIG. 1, the first conductive portion 10 is an n⁺ source portion. The n⁺ source portion functions as, for example, a source of the MOSFET.

On the substrate 5, the second conductive portion 20 is provided so as to extend in the Z-axis direction. The second conductive portion 20 is provided to be separated from the first conductive portion 10 along the X-axis direction. In the semiconductor device 110 shown in FIG. 1, the second conductive portion 20 is an n⁺ pillar portion that rises from the major surface 5a of the substrate 5 in the Z-axis direction. The n⁺ pillar portion functions as, for example, a drain of the MOSFET.

The semiconductor portion 30 is provided between the first conductive portion 10 and the second conductive portion 20. The semiconductor portion 30 is embedded between the first conductive portion 10 and the second conductive portion 20 extending in the Z-axis direction. The semiconductor portion 30 includes an n-type first semiconductor region 31 of a first impurity concentration. The first semiconductor region 31 is an n-type drift region. The first semiconductor region 31 is in contact with the second conductive portion 20 and the substrate 5.

The semiconductor portion 30 includes a p-type second semiconductor region 32 between the first semiconductor region 31 and the first conductive portion 10. The second semiconductor region 32 is a p-type base region. The second semiconductor region 32 is in contact with the first conductive portion 10 and the first semiconductor region 31.

The first electrode portion 40 is provided between the first conductive portion 10 and the second conductive portion 20 so as to extend in the Z-axis direction. The first electrode portion 40 is a gate electrode of the MOSFET. The first electrode portion 40 penetrates the second semiconductor region 32 from the first conductive portion 10 along the X-axis direction, and is formed so as to extend midway through the first semiconductor region 31.

The second electrode portion 50 is provided between the first electrode portion 40 and the second conductive portion 20 so as to extend in the Z-axis direction. The second electrode portion 50 is provided to be separated from the first electrode portion 40. The second electrode portion 50 has the same potential as, for example, the source electrode of the MOSFET. The second electrode portion 50 may be fixed to a ground potential. In the embodiment, the second electrode portion 50 is referred to as a source electrode.

The second electrode portion 50 is provided to be separated from the first electrode portion 40 along, for example, X-axis direction. The second electrode portion 50 is provided within the first semiconductor region 31 between the first electrode portion 40 and the second conductive portion 20.

The first insulating portion 60 is provided between the first electrode portion 40 and the semiconductor portion 30. The first insulating portion 60 has a first thickness t1 in the normal direction of the boundary face of the first electrode portion 40.

Here, the thickness of the first insulating portion 60 refers to a distance between the boundary face of the first electrode portion 40 and the boundary face of the semiconductor portion 30 in a gap between the first electrode portion 40 where the first insulating portion 60 is provided and the semiconductor portion 30, along the normal direction of the boundary face of the first electrode portion 40.

In the MOSFET, the first insulating portion 60 is a gate insulting film. The first insulating portion 60 is provided so as to penetrate the second semiconductor region 32 along the X-axis direction. Therefore, the first thickness t1 is the distance between the boundary face of the first electrode portion 40 and the boundary face of the second semiconductor region 32, along the normal direction of the boundary face of the first electrode portion 40.

The second insulating portion 70 is provided between the second electrode portion 50 and the semiconductor portion 30. The second insulating portion 70 has a second thickness t2 greater than the first thickness t1 in the normal direction of the boundary face of the second electrode portion 50.

Here, the thickness of the second insulating portion 70 refers to a distance between the boundary face of the second electrode portion 50 and the boundary face of the semiconductor portion 30 in a gap between the second electrode portion 50 where the second insulating portion 70 is provided and the semiconductor portion 30, along the normal direction of the boundary face of the second electrode portion 50.

In the embodiment, the second insulating portion 70 is also referred to as a source insulting film.

The semiconductor device 110 includes at least one each of the first conductive portion 10, the second conductive portion 20, the semiconductor portion 30, the first electrode portion 40, the second electrode portion 50, the first insulating portion 60 and the second insulating portion 70.

In the semiconductor device 110 shown in FIG. 1, one first conductive portion 10 (the n⁺ source portion) also extends in the Y-axis direction, and the second conductive portions 20 (the n⁺ pillar portions) are provided both on one side of and the other side of the X-axis direction with the first conductive portion 10 in the center therebetween. The first electrode portion 40 and the second electrode portion 50 are line-symmetrically provided with respect to the first conductive portion 10. A plurality of groups, each composed of the first electrode portion 40 and the second electrode portion 50 provided line-symmetrically, are spaced a predetermined distance apart along the Y-axis direction.

For example, in the semiconductor device 110, a plurality of first conductive portions 10 and a plurality of second conductive portions 20 are provided. The first conductive portions 10 and the second conductive portions 20 are alternately disposed one by one in the X-axis direction. The first electrode portion 40, the second electrode portion 50, the first insulating portion 60 and the second insulating portion 70 shown in FIG. 1 are repeatedly disposed.

A depth d2 of the second insulating portion 70 in the Z-axis direction may be equal to a depth d1 of the first insulating portion 60 in the Z-axis direction. The depth d2 is preferably greater than the depth d1. Thus, it is possible to improve the decrease in the breakdown voltage and reduce the capacity in the bottom portion of the second insulating portion 70.

In FIG. 1, for ease of description, gate wiring in electrical conduction with the first electrode portion 40 (the gate electrode), source wiring in electrical conduction with the first conductive portion 10 (the n⁺ source portion) and the second electrode portion 50 (the source electrode) and drain wiring in electrical conduction with the second conductive portion 20 (the n⁺ pillar portion) are omitted. The gate wiring and the source wiring are formed on the upper side (the side of the major surface 5a of the substrate 5) of the semiconductor device 110 shown in FIG. 1 in the Z-axis direction through an interlayer insulting film. The drain wiring is provided on the lower side (the opposite side of the major surface 5a of the substrate 5) of the semiconductor device 110 shown in FIG. 1 in the Z-axis direction.

Arrows shown in FIG. 1 represent the flow of electrons. In the semiconductor device 110, when a voltage beyond a threshold value is applied to the first electrode portion 40 (the gate electrode), a channel is formed in the second semiconductor region 32 (the p-type base region), and a current flows toward the second conductive portion 20 (the n⁺ pillar portion) opposite the first conductive portion 10 (the n⁺ source portion). Thus, it is possible to realize low on resistance.

In the semiconductor device 110, as the semiconductor portion 30 between at least one of the first insulating portion 60 and the second insulating portion 70 and the substrate 5, an electric field alleviation region 33 may be provided on the side of the first insulating portion 60 and the second insulating portion 70.

As the electric field alleviation region 33, a fifth concentration region P5 produced by a p-type semiconductor (silicon) or a sixth concentration region N6 whose resistivity is higher than that of the first semiconductor region 31 and which is produced by an n⁻ semiconductor (silicon) is used. The electric field alleviation region 33 is provided, and thus it is possible to alleviate the concentration of the electric filed at an end portion of the first conductive portion 10 on the side of the substrate 5 and to enhance the breakdown voltage.

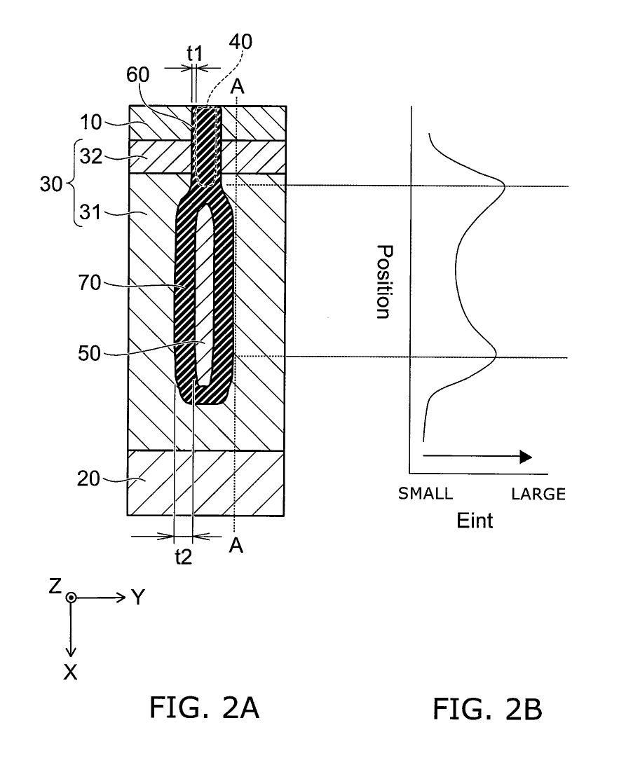

FIGS. 2A and 2B are schematic views illustrating a cross section and an electric field strength distribution.

FIG. 2A is a schematic plan view of a Z1 portion shown in FIG. 1 as viewed in the Z-axis direction. FIG. 2A shows the first electrode portion 40 and the second electrode portion 50 on one side with the first conductive portion 10 in the center. FIG. 2B illustrates the electric field strength distribution in a position along line X-X shown in FIG. 2A. In FIG. 2B, the axis of “Position” represents the position along line X-X, and the axis of “Eint” represents the electric field strength distribution.

As shown in FIG. 2A, the first insulating portion 60 having the first thickness t1 is provided between the first electrode portion 40 and the second semiconductor region 32. The second insulating portion 70 having the second thickness t2 is provided between the second electrode portion 50 and the first semiconductor region 31. The second thickness t2 is greater than the first thickness t1.

As described above, the second thickness t2 of the second insulating portion 70 (the source insulating film) is greater than the first thickness t1 of the first insulating portion 60 (the gate insulating film), and thus a field plate trench structure (hereinafter simply referred to as an “FP structure”) for alleviating the concentration of the electric field at an end portion of the first electrode portion 40 (the gate electrode) on the side of the second conductive portion 20 is realized. In this way, the gate capacitance is reduced as compared with a structure having no FP structure.

In the FP structure described above, an electric field is present on the side of the second conductive portion 20 (the n⁺ pillar portion) of the second electrode portion 50 (the source electrode), and an electric field is also present in the boundary portion between the first insulating portion 60 (the gate insulating film) and the second insulating portion 70 (the source insulating film). In this way, as shown in FIG. 2B, two crests of the electric field are provided, and these two crests are balanced, with the result that the breakdown voltage can be enhanced. Even if the first impurity concentration in the first semiconductor region 31 (the n-type drift region) is reduced, it is also possible to obtain sufficient breakdown voltage. Therefore, it is possible to reduce the on resistance.

A reference example will now be described.

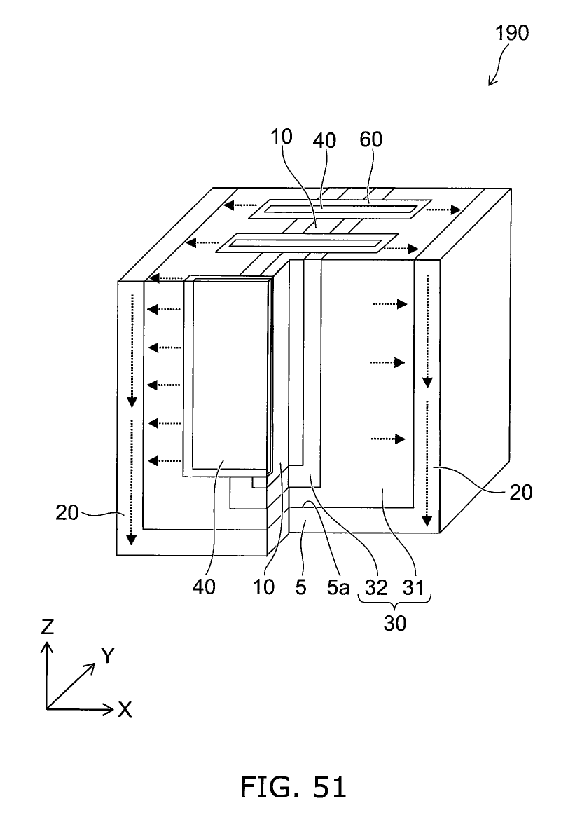

FIG. 51 is a schematic perspective view showing the reference example.

As shown in FIG. 51, in a semiconductor device 190 according to the reference example, the first electrode portion 40 that is the gate electrode is provided, as viewed in the Z-axis direction, from the first conductive portion 10 midway through the first semiconductor region 31. In the semiconductor device 110 illustrated in FIG. 1, the second electrode portion 50 is provided to be separated from the first electrode portion 40 whereas, in the semiconductor device 190 illustrated in FIG. 51, the second electrode portion 50 is not provided.

The thickness of the first insulating portion 60 of the semiconductor device 190 is constant. Therefore, as an FET area (an opposite area between the gate electrode and the gate insulating film in the MOSFET) is substantially increased, the gate capacitance is increased. When the gate capacitance is increased, if the semiconductor device 190 is used in a power supply circuit or the like required for high-speed switching, a switching loss is increased. Moreover, since the thickness of the bottom portion of the first insulating portion 60 is small, the breakdown voltage is likely to be reduced.

By contrast, in the semiconductor device 110 according to the embodiment, the FP structure formed with the second electrode portion 50 and the second insulating portion 70 is provided, it is possible to enhance the breakdown voltage and reduce the gate capacity.

A method of manufacturing the semiconductor device 110 will now be described.

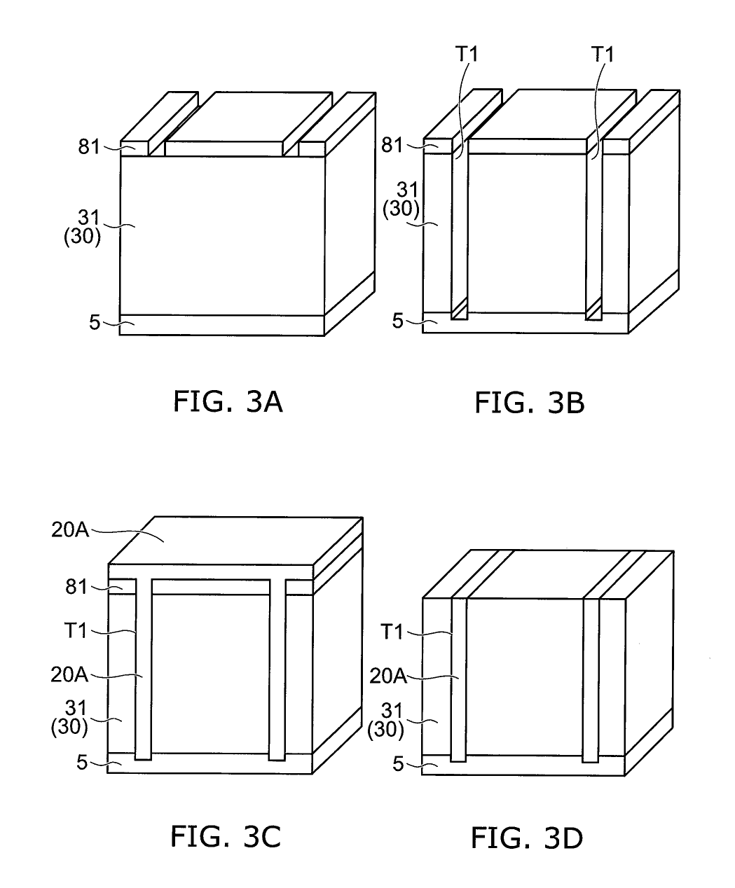

FIGS. 3A to 8 are schematic perspective views illustrating the method of manufacturing the semiconductor device.

First, in the processes shown in FIGS. 3A to 3D, the substrate 5, the second conductive portion 20 and the semiconductor portion 30 are formed.

First, as shown in FIG. 3A, on the major surface 5a of the substrate 5, the first semiconductor region 31 of the semiconductor portion 30 is, for example, epitaxially grown. The substrate 5 is, for example, an n⁺ silicon wafer. The first semiconductor region 31 is, for example, an n-type epitaxial layer. Then, the mask pattern 81 is formed on the first semiconductor region 31. As the mask pattern 81, for example, silicon oxide is used. In the mask pattern 81, an opening is provided by photolithography in a position where the second conductive portion 20 is formed.

Then, as shown in FIG. 3B, through the mask pattern 81 in which the opening is provided, the first semiconductor region 31 and the substrate 5 are etched. For the etching, for example, reactive ion etching (RIE) is used. Thus, a trench T1 is formed so deeply that it extends from the first semiconductor region 31 midway through the substrate 5. The trench T1 is formed so as to extend in the Y-axis direction.

Then, as shown in FIG. 3C, a second conductive portion material 20A is embedded within the trench T1. As the second conductive portion material 20A, for example, a polysilicon of a high impurity concentration is used. The second conductive portion material 20A is formed to reach an area above the mask pattern 81.

Then, the second conductive portion material 20A and the mask pattern 81 are removed until the opening portion of the trench T1 is exposed. The second conductive portion material 20A and the mask pattern 81 are removed by, for example, chemical mechanical polishing (CMP). Thus, as shown in FIG. 3D, the second conductive portion 20 is formed within the trench T1. The second conductive portion 20 is provided so as to extend from the major surface 5a of the substrate 5 in the Z-axis direction and also extend in the Y-axis direction.

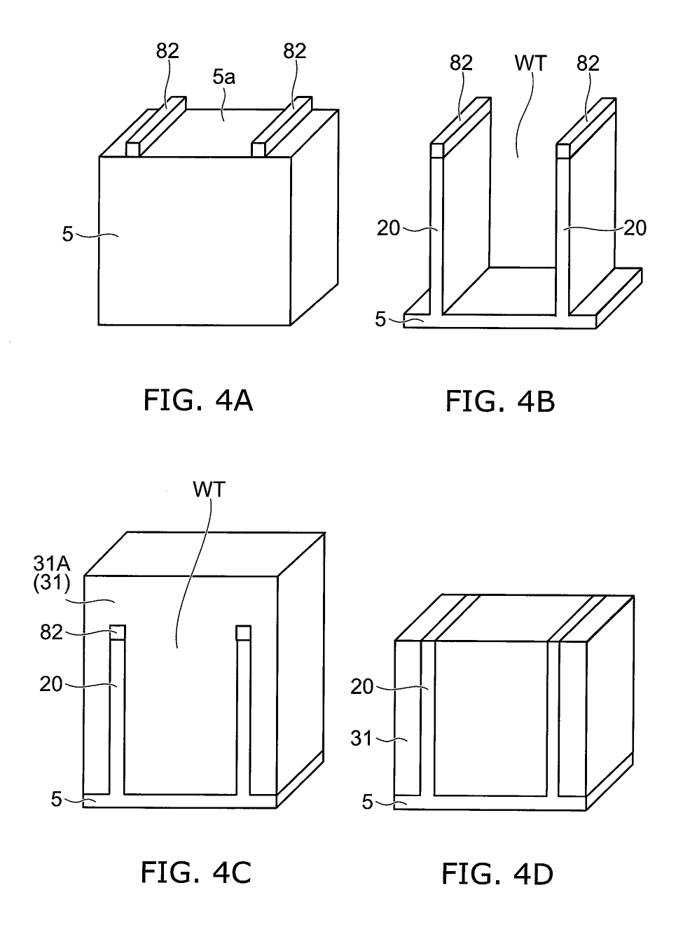

Another method of forming the second conductive portion 20 will now be described with reference to FIGS. 4A to 4D.

First, as shown in FIG. 4A, on the major surface 5a of the substrate 5, a mask pattern 82 is formed. As the mask pattern 82, for example, silicon oxide is used. In the mask pattern 82, an opening is formed by photolithography in a position other than the position where the second conductive portion 20 is formed.

Then, as shown in FIG. 4B, through the mask pattern 82, the substrate 5 is etched. A portion removed by this etching is referred to as a wide trench WT. In contrast, a portion masked by the mask pattern 82 serves as the second conductive portion 20 extending from the substrate 5 in the Z-axis direction.

Then, as shown in FIG. 4C, on the substrate 5, a first semiconductor material 31A is, for example, epitaxially grown. The first semiconductor material 31A is, for example, an n-type silicon. The first semiconductor material 31A is embedded between a plurality of second conductive portions 20 on the substrate 5, that is, within the wide trench WT. The first semiconductor material 31A embedded within the wide trench WT serves as the first semiconductor region 31.

Then, part of the first semiconductor material 31A A is removed. Here, the first semiconductor material 31A is removed until an upper portion of the second conductive portion 20 is exposed. The first semiconductor material 31A is removed by, for example, CMP. Thus, as shown in FIG. 4D, on the substrate 5, the second conductive portion 20 and the first semiconductor region 31 are formed. The second conductive portion 20 is formed so as to extend from the major surface 5a of the substrate 5 in the Z-axis direction and also extend in the Y-axis direction.

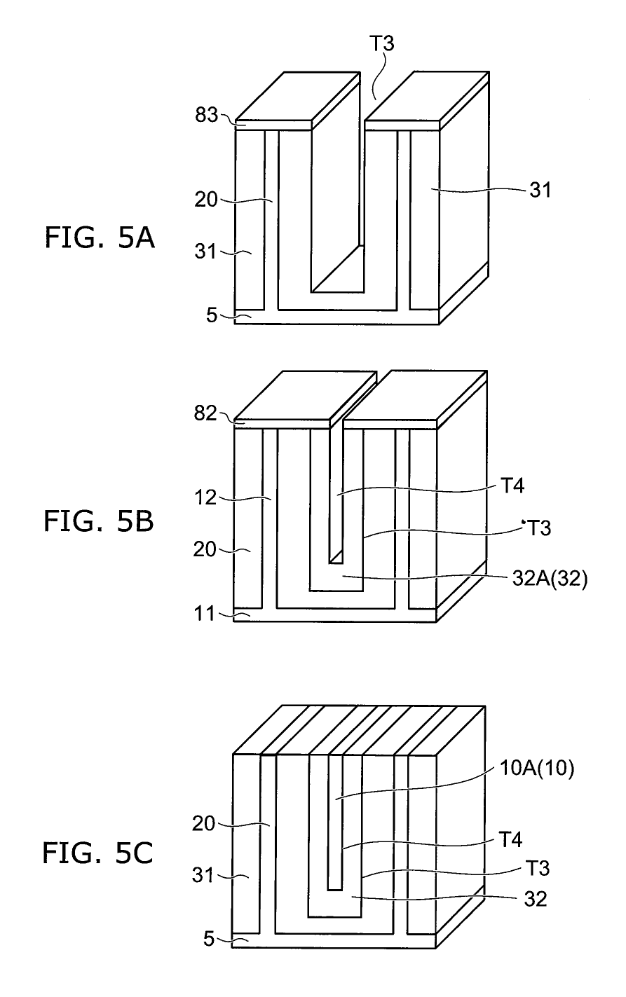

The second conductive portion 20 is formed by any one of the processes shown in FIGS. 3A to 3D and 4A to 4D, and thereafter the processes shown in FIGS. 5A to 5C to 8 are sequentially performed. FIGS. 5A to 5C to 8 illustrate a case where the second conductive portion 20 is formed by the processes shown in FIG. 4A to 4D.

First, as shown in FIG. 5A, a mask pattern 83 is formed on the first semiconductor region 31 and the second conductive portion 20. As the mask pattern 83, for example, silicon oxide is used. In the mask pattern 83, an opening is provided by photolithography in a position where the second semiconductor region 32 is formed.

Then, through the mask pattern 83, the first semiconductor region 31 is etched. For the etching, for example, reactive ion etching (RIE) is used. Thus, a trench T3 is formed so deeply that it extends from the upper face of the first semiconductor region 31 midway through. The trench T3 is formed so as to extend in the Y-axis direction.

Then, as shown in FIG. 5B, a second semiconductor material 32A is embedded within the trench T3. The second semiconductor material 32A is formed so as to be embedded within the trench T3 by, for example, epitaxial growth. The second semiconductor material 32A is, for example, a p-type silicon.

Thereafter, a mask pattern 84 is formed on the second semiconductor material 32A, the first semiconductor region 31 and the second conductive portion 20. As the mask pattern 84, for example, silicon oxide is used. In the mask pattern 84, an opening is provided by photolithography in a position where the first conductive portion 10 is formed.

Then, through the mask pattern 84, the second semiconductor material 32A is etched. For the etching, for example, reactive ion etching (RIE) is used. Thus, a trench T4 is formed so deeply that it extends from the upper face of the second semiconductor material 32A midway through. The trench T4 is formed so as to extend in the Y-axis direction.

Then, as shown in FIG. 5C, a first conductive portion material 10A is embedded within the trench T4. The first conductive portion material 10A is formed so as to be embedded within the trench T4 by, for example, epitaxial growth. The first conductive portion material 10A is, for example, an n⁺-type silicon. The mask pattern 84 is removed by CMP. Thus, the first conductive portion 10 is formed within the trench T4. The second semiconductor region 32 is formed within the trench T3 outside the first conductive portion 10.

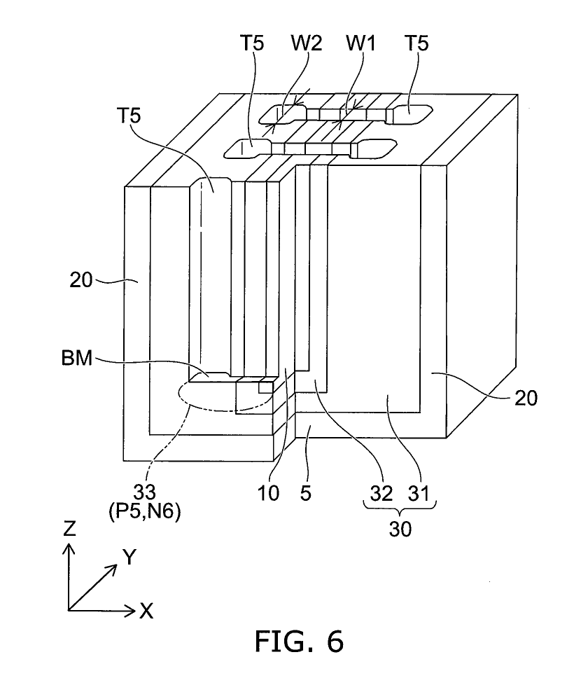

Then, as shown in FIG. 6, a trench T5 (a first trench) along the X-axis direction is formed. The depth of the trench T5 along the Z-axis direction is shallower than that of the first conductive portion 10 along the Z-axis direction. An opening of the trench T5 as viewed in the Z-axis direction penetrates the first conductive portion 10 and the second semiconductor region 32, and is provided midway through the first semiconductor region 31.

In an example shown in FIG. 6, the opening of the trench T5 is formed so as to extend toward both one side of and the other side of the X-axis direction with the first conductive portion 10 in the center. Thus, a combination of the first electrode portion 40 and the second electrode portion 50 can be line-symmetrically formed from the trench T5 with respect to the first conductive portion 10.

The opening of the trench T5 as viewed in the Z direction has a first width w1 and a second width w2 along the Y-axis direction. The second width w2 is greater than the first width w1. At a portion of the first width w1, the first electrode portion 40 is formed. At a portion of the second width w2, the second electrode portion 50 is formed. By the first width w1 and the second width w2 of the trench T5, it is possible to set the first thickness t1 of the first insulating portion 60 and the second thickness t2 of the second insulating portion 70.

By changing the shape of the opening of the trench T5 as viewed in the Z-axis direction, it is possible to deal with various variations on the structure (the structure of the first electrode portion 40, the second electrode portion 50, the first insulating portion 60 and the second insulating portion 70) within the trench T5.

When the electric field alleviation region 33 is provided, an impurity is implanted into a bottom portion BM of the trench T5, and thus the electric field alleviation region 33 is formed. For example, boron (B) is ion-implanted obliquely into the bottom portion BM of the trench T5, and is thermally diffused. The electric field alleviation region 33 formed by the ion implantation of B and the thermal diffusion is a sixth concentration region N4 of an n⁻ type semiconductor that is lower in impurity concentration than the fifth concentration region or the semiconductor portion 30 (the first semiconductor region 31).

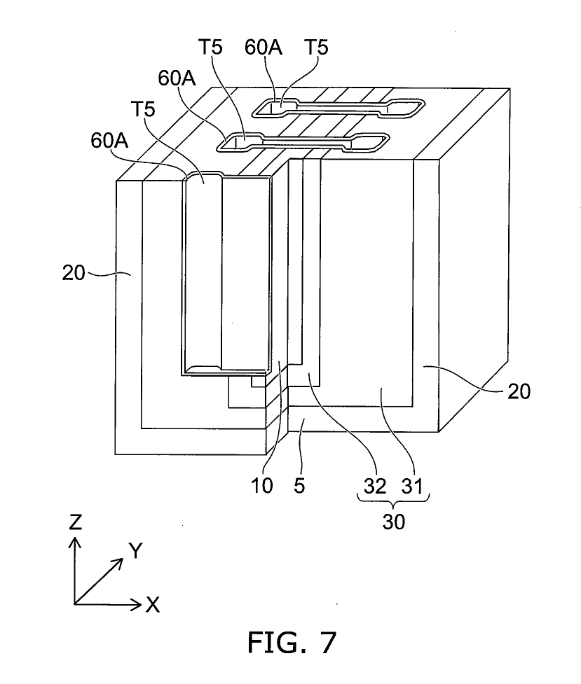

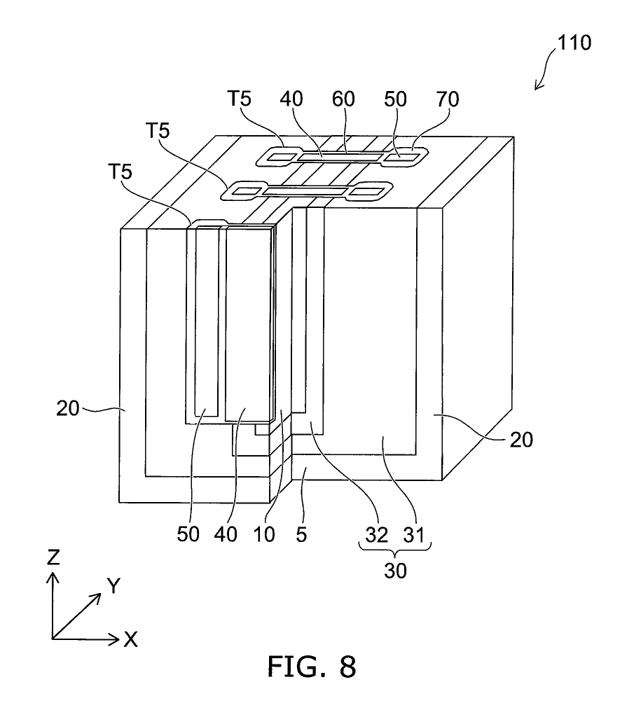

Then, as shown in FIG. 7, an insulating film 60A is formed on the inside wall of the trench T5. The insulating film 60A is, for example, a thermal oxide film of silicon. As shown in FIG. 8, the first electrode portion 40 and the second electrode portion 50 are formed within the trench T5. As the first electrode portion 40 and the second electrode portion 50, for example, a polysilicon is used.

The insulating film 60A provided between the first electrode portion 40 and the second semiconductor region 32 serves as the first insulating portion 60. The insulating film 60A provided between the second electrode portion 50 and the first semiconductor region 31 serves as the second insulating portion 70.

In this way, the semiconductor device 110 is completed.

According to the manufacturing method described above, the shape of the opening of the trench T5 as viewed in the Z-axis direction is changed, and thus it is possible to easily realize various FP structures. That is, when, in a so-called plane-type MOS structure, the FP structure is provided using a trench, it is necessary to provide a portion of a wide width for forming a source insulating film at a position midway through in the direction (the direction from the opening to the bottom portion) of depth of the trench, and therefore it is very difficult to achieve the manufacturing. In the manufacturing method described above, since a portion of a wide width for forming the source insulting film appears on the opening face of the trench T5, it is possible to easily manufacture even a complicated FP structure which it is impossible for the so-called plane-type MOS structure to realize.

In the embodiment, the manufacturing method described above is applied, and thus various structures within the trench T5 in the semiconductor device 110 are realized.

Variations of the structure within the trench T5 will now be described.

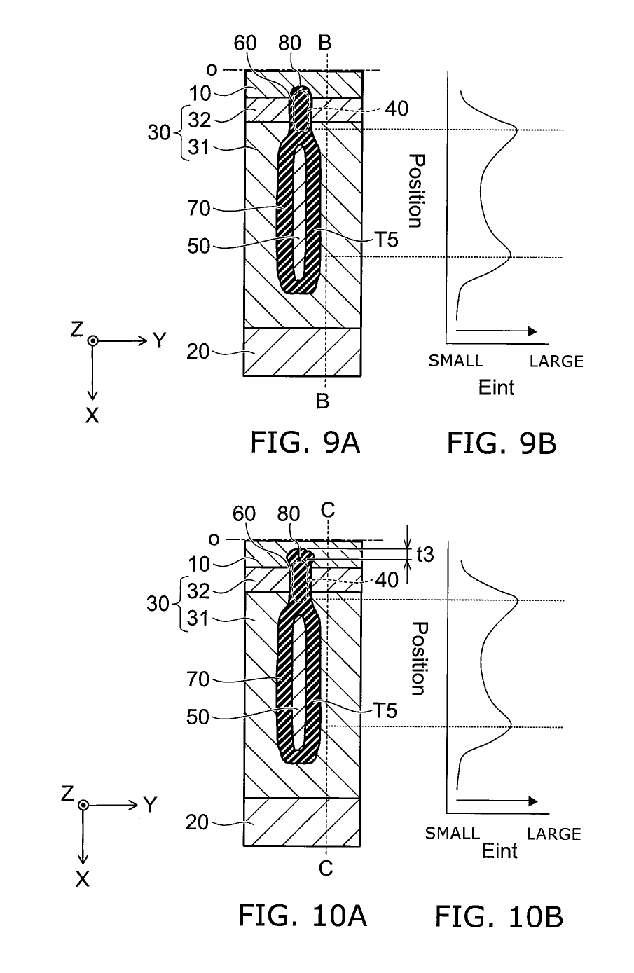

FIGS. 9A to 17B are diagrams illustrating the variations of the structure within the trench.

In FIGS. 9A and 9B to 17A and 17B, FIGS. 9A, 10A, 11A, 12A, 13A 14A, 15A, 16A and 17A are schematic plan views of the Z1 portion shown in FIG. 1, and FIGS. 9B, 10B, 11B, 12B, 13B 14B, 15B, 16B and 17B illustrate an electric field strength distribution in a position along a line shown in FIGS. 9A, 10A, 11A, 12A, 13A 14A, 15A, 16A and 17A. In those figures, FIGS. 9A, 10A, 11A, 12A, 13A 14A, 15A, 16A and 17A show the first electrode portion 40 and the second electrode portion 50 on one side with the first conductive portion 10 in the center. Therefore, when a combination of the first electrode portion 40 and the second electrode portion 50 is line-symmetrically provided with respect to the first conductive portion 10, portions obtained by reversing the individual portions shown in FIGS. 9A, 10A, 11A, 12A, 13A 14A, 15A, 16A and 17A with respect to an alternate long and short dashed line o in the figures are formed. In the following description, for ease of description, only a combination of the first electrode portion 40 and the second electrode portion 50 on one side with the first conductive portion 10 in the center will be illustrated.

In the structure within the trench shown in FIG. 9A, the opening of the trench T5 as viewed in the Z-axis direction is provided along the X-axis direction from midway through the first conductive portion 10 to midway through the first semiconductor region 31. That is, the opening of the trench T5 as viewed in the Z-axis direction does not penetrate the first conductive portion 10.

Since the opening of the trench T5 does not penetrate the first conductive portion 10, a third insulting portion 80 is provided between the first electrode portion 40 and the first conductive portion 10. The third insulting portion 80 is formed integrally with the first insulating portion 60.

As shown in FIG. 9B, two crests of the electric field are provided on line B-B of the structure within the trench illustrated in FIG. 9A, and these two crests are balanced, with the result that the breakdown voltage can be enhanced.

In the structure described above, it is possible to reduce a region of the insulating portion in contact with the first conductive portion 10 as compared with the structure where the opening of the trench T5 penetrates the first conductive portion 10. Thus, it is possible to reduce the gate capacitance and enlarge the conductive region of the first conductive portion 10. The reduction of the gate capacitance and the enlargement of the conductive region of the first conductive portion 10 allow low on resistance to be achieved by the decrease in the source resistance.

In the structure within the trench shown in FIG. 10A, as with the structure shown in FIG. 9A, the opening of the trench T5 as viewed in the Z-axis direction does not penetrate the first conductive portion 10. In an example shown in FIG. 10A, the thickness (a third thickness t3) of the third insulting portion 80 is greater than the first thickness t1 of the first insulating portion 60. Here, the thickness of the third insulting portion 80 refers to a distance between the boundary face of the first electrode portion 40 and the boundary face of the first conductive portion 10 in a gap between the first electrode portion 40 where the third insulting portion 80 is provided and the first conductive portion 10, along the normal direction of the boundary face of the first electrode portion 40.

As shown in FIG. 10B, two crests of the electric field are provided on line C-C of the structure within the trench illustrated in FIG. 10A, and these two crests are balanced, with the result that the breakdown voltage can be enhanced.

In the structure described above, since the third thickness t3 of the third insulting portion 80 is great as compared with the structure shown in FIG. 9A, it is possible to further reduce the gate capacitance. Thus, it is possible to further reduce the low on resistance.

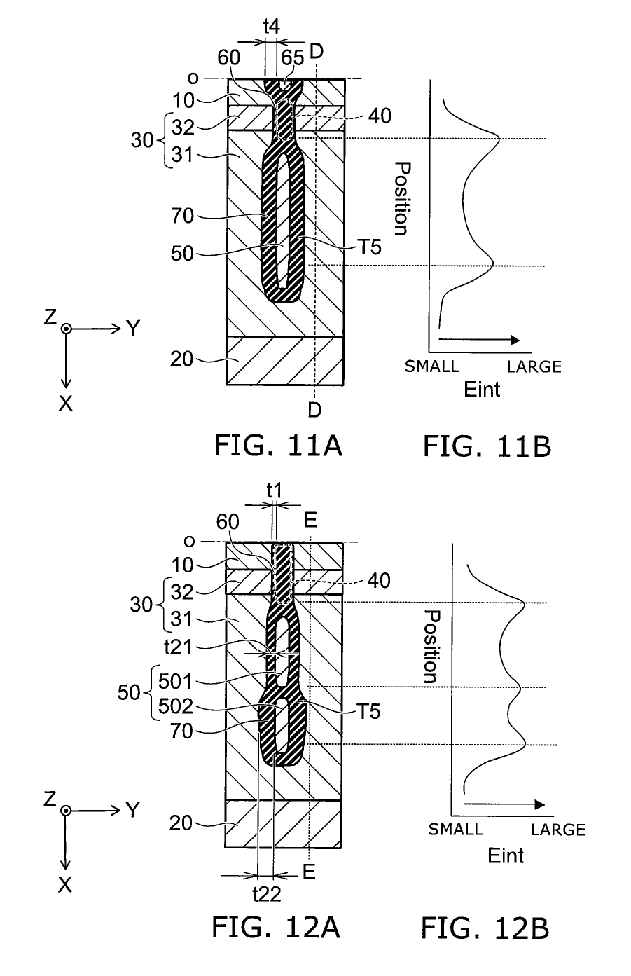

In the structure within the trench shown in FIG. 11A, on the side of the first electrode portion 40 and the first conductive portion 10, a third electrode portion 65 is provided. The third electrode portion 65 has the same potential as the second electrode portion 50. A fourth insulating portion 90 is provided between the third electrode portion 65 and the first conductive portion 10. The thickness (a fourth thickness t4) of the fourth insulating portion 90 is greater than the first thickness t1 of the first insulating portion 60. The fourth thickness t4 is approximately equal to, for example, the second thickness t2 of the second insulating portion 70.

Here, the thickness of the fourth insulating portion 90 refers to a distance between the boundary face of the first electrode portion 40 and the boundary face of the first conductive portion 10 in a gap between the first electrode portion 40 where the fourth insulating portion 90 is provided and the first conductive portion 10, along the normal direction of the boundary face of the first electrode portion 40.

As shown in FIG. 11B, two crests of the electric field are provided on line D-D of the structure within the trench illustrated in FIG. 11A, and these two crests are balanced, with the result that the breakdown voltage can be enhanced.

In the structure described above, the insulating portion (the fourth insulating portion 90) in contact with the first conductive portion 10 is increased in thickness, and thus it is possible to further reduce the gate capacitance as compared with the structure shown in FIG. 10A. Thus, it is possible to further reduce the low on resistance.

In the structure within the trench shown in FIG. 12A, the second electrode portion 50 is divided into two sub-electrode portions 501 and 502. The sub-electrode portions 501 and 502 are disposed away from each other along the X-axis direction. The thickness t22 of the second insulating portion 70 provided between the sub-electrode portion 502 and the first semiconductor region 31 is greater than the thickness t21 of the second insulating portion 70 provided between the sub-electrode portion 501 and the first semiconductor region 31. That is, the thickness of the second insulating portion 70 is gradually increased from the first conductive portion 10 to the second conductive portion 20.

As shown in FIG. 12B, three crests of the electric field are provided on line E-E of the structure within the trench illustrated in FIG. 12A. That is, the electric field is strong at an end portion of the first electrode portion 40 on the side of the second conductive portion 20, at an end portion of the sub-electrode portion 501 on the side of the second conductive portion 20 and at an end portion of the sub-electrode portion 502 on the side of the second conductive portion 20.

In the structure described above, the electric distribution can be shared by the three crests, and thus it is possible to enhance the breakdown voltage. Even if the first impurity concentration in the first semiconductor region 31 is increased, it is possible to obtain sufficient breakdown voltage, with the result that the on resistance can be reduced. Although, in the example shown in FIG. 12A, the second electrode portion 50 is divided into the two sub-electrode portions 501 and 502, the second electrode portion 50 may be divided into a larger number of sub-electrode portions.

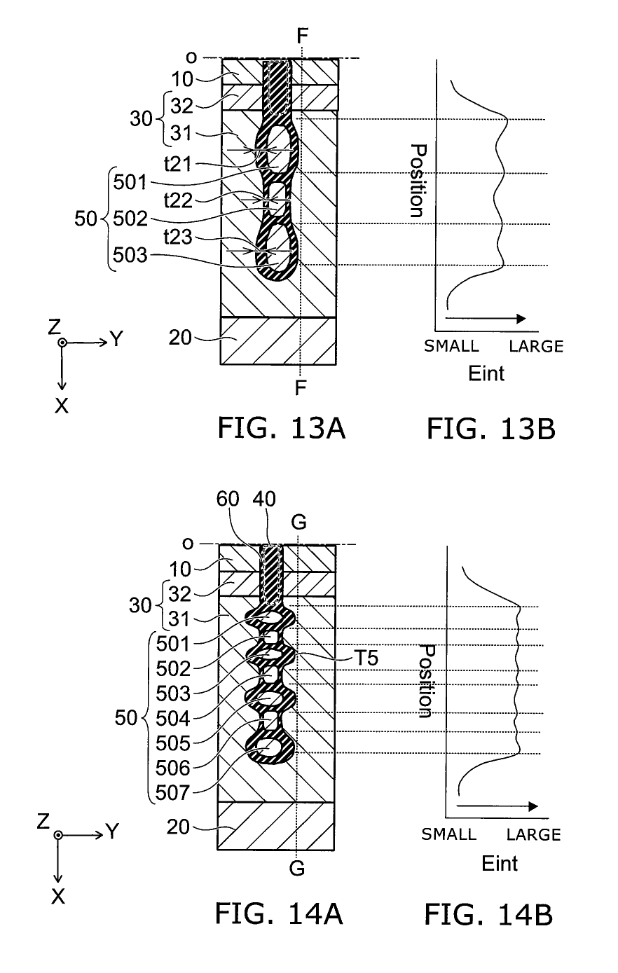

In the structure within the trench shown in FIG. 13A, the second electrode portion 50 is divided into three sub-electrode portions 501, 502 and 503. The sub-electrode portions 501, 502 and 503 are disposed away from each other along the X-axis direction.

The thickness t21 of the second insulating portion 70 provided between the sub-electrode portion 501 and the first semiconductor region 31, the thickness t22 of the second insulating portion 70 provided between the sub-electrode portion 502 and the first semiconductor region 31 and a thickness t23 of the second insulating portion 70 provided between the sub-electrode portion 503 and the first semiconductor region 31 are repeatedly increase and decreased from the first conductive portion 10 to the second conductive portion 20.

In the example shown in FIG. 13A, the thickness t22 is smaller than the thickness t21, and the thickness t23 is greater than the thickness t22. That is, the thickness of the second insulating portion 70 becomes great, then becomes small and then becomes great in this order as the second insulating portion 70 extends from the first conductive portion 10 to the second conductive portion 20.

As shown in FIG. 13B, four crests of the electric field are provided on line F-F of the structure within the trench illustrated in FIG. 13A. That is, the electric field is strong at the end portion of the first electrode portion 40 on the side of the second conductive portion 20, at the end portion of the sub-electrode portion 501 on the side of the second conductive portion 20, at the end portion of the sub-electrode portion 502 on the side of the second conductive portion 20 and at an end portion of the sub-electrode portion 503 on the side of the second conductive portion 20.

In the structure described above, the electric distribution can be shared by the four crests, and thus it is possible to reduce the troughs of the electric field. In this way, it is possible to further enhance the breakdown voltage. Even if the first impurity concentration in the first semiconductor region 31 is increased, it is possible to obtain sufficient breakdown voltage, with the result that the on resistance can be further reduced.

Although, in the example shown in FIG. 13A, the second electrode portion 50 is divided into the three sub-electrode portions 501, 502 and 503, the second electrode portion 50 may be divided into a larger number of sub-electrode portions.

The structure within the trench shown in FIG. 14A is an example where the second electrode portion 50 shown in FIG. 13A is divided into a larger number of sub-electrode portions. In the structure shown in FIG. 14A, the second insulating portion 60 is divided into seven sub-electrode portions 501 to 507.

The thickness of the second insulating portion 70 provided between each of the sub-electrode portions 501 to 507 and the first semiconductor region 31 is alternately increased and decreased.

As shown in FIG. 14B, as the number of times the second insulating portion 60 is divided is increased, the troughs of the electric field strength are reduced. FIG. 14B illustrates an electric field strength distribution on line G-G of the structure within the trench illustrated in FIG. 14A. Since the seven sub-electrode portions 501 to 507 are provided, the electric field strength distribution is substantially flat.

In the structure described above, it is possible to further enhance the breakdown voltage and reduce the on resistance.

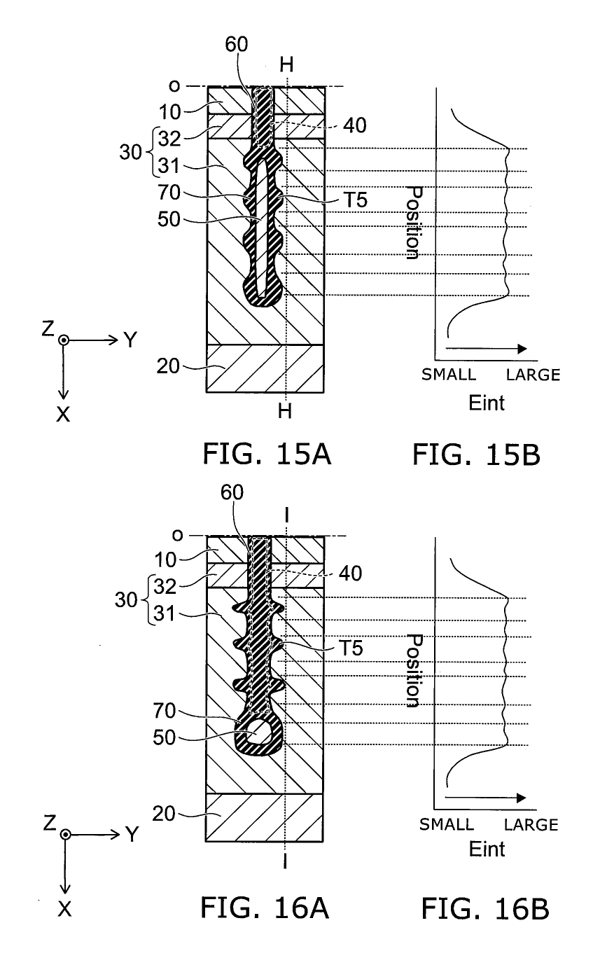

In the structure within the trench shown in FIG. 15A, along the X-axis direction of the second electrode portion 50, the thickness of the second insulating portion 70 is repeatedly increased and decreased. In this structure, the width of the second electrode portion 50 along the Y-axis direction is substantially constant. In contrast, the width of the trench T5 along the Y-axis direction is repeatedly increased and decreased along the X-axis direction. As the width of the trench T5 is increased and decreased, the thickness of the second insulating portion 70 is repeatedly increased and decreased.

As shown in FIG. 15B, the electric field strength distribution on line H-H of the structure within the trench illustrated in FIG. 15A is substantially flat. In this structure, it is possible to further enhance the breakdown voltage. Even if the first impurity concentration in the first semiconductor region 31 is increased, it is possible to obtain sufficient breakdown voltage, with the result that the on resistance can be further reduced.

In the structure within the trench shown in FIG. 16A, the first electrode portion 40 penetrates the first conductive portion 10 and the second semiconductor region 32 along the X-axis direction, and extends midway through the first semiconductor region 31. The thickness of the first insulating portion 60 provided between the first electrode portion 40 and the first semiconductor region 31 is repeatedly increased and decreased from the first conductive portion 10 to the second conductive portion 20.

As shown in FIG. 16B, the electric field strength distribution on line I-I of the structure within the trench illustrated in FIG. 16A is substantially flat. In this structure, it is possible to further enhance the breakdown voltage. Even if the first impurity concentration in the first semiconductor region 31 is increased, it is possible to obtain sufficient breakdown voltage, with the result that the on resistance can be further reduced.

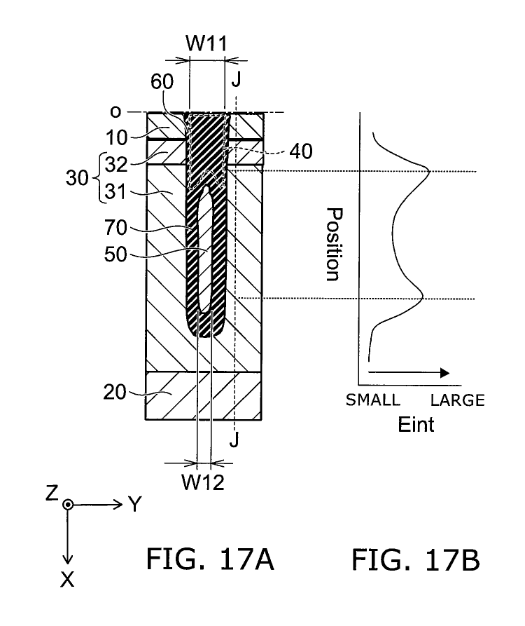

In the structure within the trench shown in FIG. 17A, the width w12 of the first electrode portion 40 along the Y-axis direction is greater than the width w12 of the second electrode portion 50 along the Y-axis direction. In this structure, the width of the trench T5 along the Y-axis direction is substantially constant. Therefore, the width w12 of the second electrode portion 50 is narrowed than the width w11 of the first electrode portion 40, and thus it is possible to increase the thickness of the second insulating portion 70 as compared with the thickness of the first insulating portion 60.

As shown in FIG. 17B, on line J-J of the structure within the trench illustrated in FIG. 17A, two crests of the electric field are provided, and these crests are balanced, with the result that the breakdown voltage can be enhanced. In this structure, the width w11 of the first electrode portion 40 is greater than those of the other structures, and thus it is possible to reduce the resistance (the gate resistance) of the first electrode portion 40.

A method of manufacturing the structure within the trench discussed above will now be described.

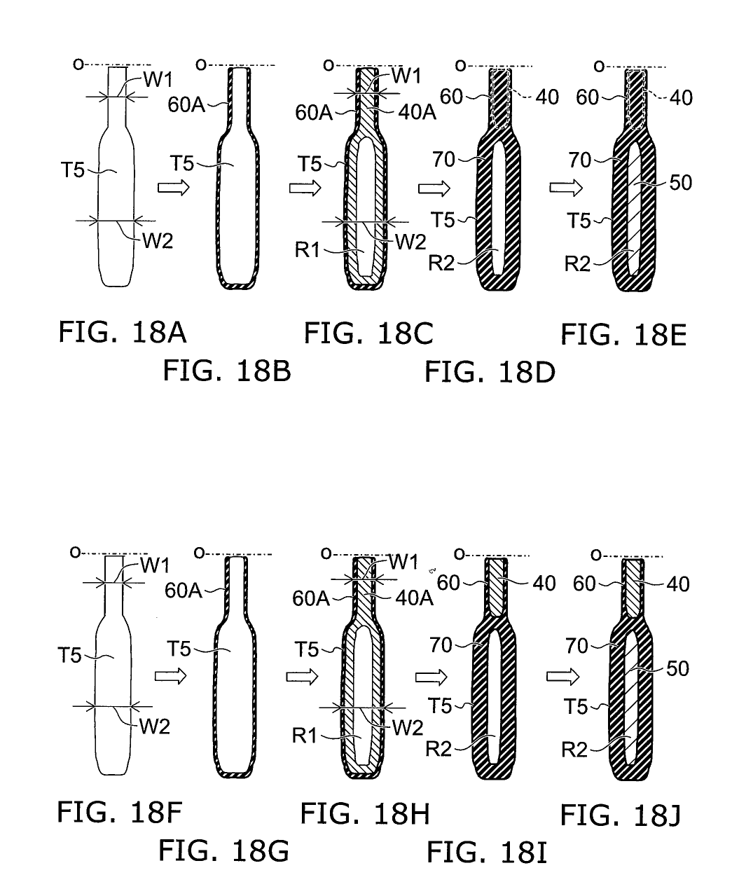

FIGS. 18A to 18J are schematic views illustrating the method (a first method) of manufacturing the structure within the trench.

FIGS. 18A to 18E show schematic plan views of the Z1 portion shown in FIG. 1 in order of the processes.

FIGS. 18F to 18J show schematic cross-sectional views of the Z2 portion shown in FIG. 1 according to FIGS. 18A to 18E. For ease of description, only the state of the interior of the trench T5 will be illustrated.

The manufacturing method shown in FIGS. 18F to 18J are examples of the method of manufacturing the structures within the trenches shown in FIGS. 2A, 9A, 10A and 11A. In the methods of manufacturing these structures within the trenches, only the shape of the opening of the trench T5 as viewed in the Z-axis direction, that is, the shape of the opening of the mask pattern is different. Therefore, the structure within the trench shown in FIG. 2A will be described as a typical example.

First, as shown in FIGS. 18A to 18F, the trench T5 is formed. The widths along the Y-axis direction of the opening, as viewed in the Z-axis direction, of the trench T5 are the widths w1 and w2. The width w2 is larger than the width w1. As the trench T5 extends from the portion of the width w1 to the portion of the width w2, the width gradually becomes larger. Thus, the shape of the opening of the trench T5 is bottle-shaped.

Next, as shown in FIGS. 18B and 18G, the insulating film 60A is formed on the inside wall of the trench T5. The insulating film 60A is, for example, a thermal oxide film. Then, as shown in FIGS. 18C to 18H, a first electrode film 40A is formed on the insulating film 60A within the trench T5. The first electrode film 40A is, for example, a polysilicon containing an impurity. The first electrode film 40A is deposited on the insulating film 60A.

Here, the first electrode film 40A is formed such that the first electrode film 40A is embedded in the portion of the trench T5 of the width w1, and that a space R1 is left in the portion of the trench T5 of the width w2. That is, the first electrode film 40A is embedded in the portion (the portion of the width w1) of the trench T5 of a narrow width, and the first electrode film 40A is incompletely embedded in the portion (the portion of the width w2) of the trench T5 of a wide width.

Then, as shown in FIGS. 18D to 18I, a portion of the first electrode film 40A is oxidized. That is, when, for example, a polysilicon is used as the first electrode film 40A, oxidation processing is performed in an atmosphere of oxygen and the portion is changed into a silicon oxide film. The oxidation of the first electrode film 40A progresses from a portion exposed to the space R1 and the upper face (exposed portion) of the portion of the width w1.

By this oxidation, the second insulating portion 70 is formed in the portion of the width w2. The first electrode film 40A exposed to the space R1 is sufficiently oxidized, and thus it is possible to form the second insulating portion 70 of a great thickness.

In contrast, although the portion of the width w1 is oxidized from the upper face (the exposed portion) to a portion of the interior, a portion that is left without being oxidized serves as the first electrode portion 40. The insulating film 60A present between the first electrode portion 40 and the inside wall of the trench T5 serves as the first insulating portion 60. Since the first electrode portion 40 is a portion of the first electrode film 40A that is left without being oxidized, the thickness of the first insulating portion 60 in contact with the first electrode portion 40 remains the same as the thickness of the film when the insulating film 60A is formed. That is, the thickness of the gate insulating film is accurately set.

By the oxidation processing described above, the space R1 serves as a space R2 that is slightly smaller than the space R1. This is because the thickness of the first electrode film 40A formed in the portion of the width w2 is increased by the oxidation.

Next, as shown in FIGS. 18E to 18J, the second electrode portion 50 is formed in the space R2 surrounded by the second insulating portion 70. For example, a polysilicon is used as the second electrode portion 50. The third electrode portion 65 shown in FIG. 11A is formed in the same process as the second electrode portion 50. By the processes described above, the structure within the trench is completed.

Another example of the method (the first method) of manufacturing the structure within the trench illustrated in FIGS. 18A to 18J will now be described.

In another example, the processes illustrated in FIGS. 18A to 18C and FIGS. 18F to 18H are the same as those described previously.

Then, through the first electrode film 40A in the portion of the trench T5 of the width w2, such as by a lingetter process, phosphorus (P) is diffused as a high concentration impurity, into the first electrode film 40A (polysilicon).

Afterward, after the phosphorus glass is removed, the first electrode film 40A (polysilicon) in the portion of the width w2 is all oxidized under an atmosphere of oxygen. Therefore, an oxide film (the second insulating portion 70) sufficiently thicker than the first insulating portion 60 of the width w1 is formed.

Here, since the first insulating portion 60 is surrounded by the first electrode film 40A (polysilicon), the polysilicon in the boundary between the gate oxide film and the source oxide film is oxidized, and the thickness of the first insulating portion 60 in contact with the first electrode portion 40 remains the same as the thickness of the film when the insulating film 60A is formed.

After that, as shown in FIGS. 18E to 18J, the second electrode portion 50 is formed in the space R2 surrounded by the second insulating portion 70. By the processes described above, the structure within the trench is completed. When the first electrode film 40A is deposited, the first electrode film 40A may or may not contain an impurity.

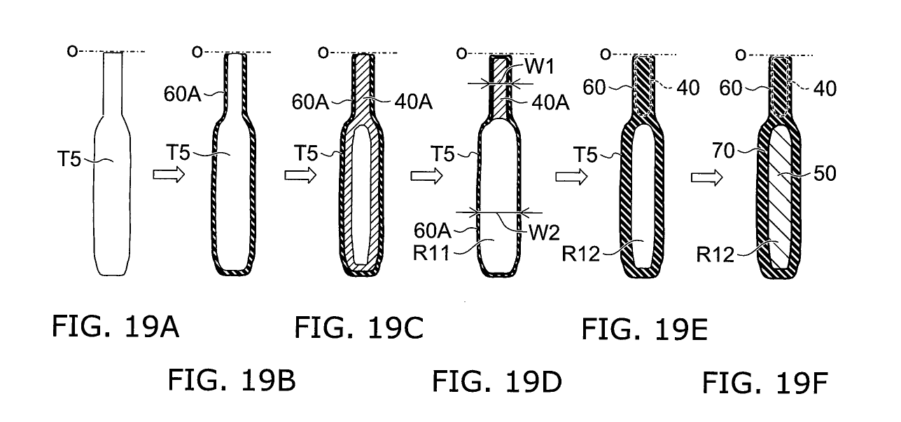

FIGS. 19A to 19F are schematic views illustrating the method (a second method) of manufacturing the structure within the trench.

FIGS. 19A to 19F show schematic plan views of the Z1 portion shown in FIG. 1 in order of the processes. For ease of description, only the state of the interior of the trench T5 will be illustrated.

The manufacturing method shown in FIGS. 19A to 19F are examples of the method of manufacturing the structures within the trenches shown in FIGS. 2A, 9A, 10A and 11A. In the methods of manufacturing these structures within the trenches, only the shape of the opening of the trench T5 as viewed in the Z-axis direction, that is, the shape of the opening of the mask pattern is different. The structure within the trench shown in FIG. 2A will be described as a typical example.

First, the trench T5 shown in FIG. 19A, the insulating film 60A shown in FIG. 19B and the first electrode film 40A shown in FIG. 19C are formed. These processes are the same as shown in FIGS. 18A to 18C.

Then, as shown in FIG. 19D, the first electrode film 40A provided in the portion of the trench T5 of the width w2 is removed. The first electrode film 40A is removed by, for example, chemical dry etching (CDE). Therefore, a space R11 is provided in the portion of the trench T5 of the width w2.

Then, as shown in FIG. 19E, a portion of the first electrode film 40A is oxidized. That is, when for example, a polysilicon is used as the first electrode film 40A, oxidation processing is performed under an atmosphere of oxygen, and the portion is changed into a silicon oxide film. The oxidation of the first electrode film 40A progresses from a portion exposed to the space R11 and the upper face (exposed portion) of the portion of the width w1. When the first electrode film 40A is not left in the portion of the trench T5 of the width w2, the thickness of the insulating film 60A is increased.

By the oxidation described above, the second insulating portion 70 is formed in the portion of the width w2. In contrast, although the portion of the width w1 is oxidized from the upper face (the exposed portion) to a portion of the interior, a portion that is left without being oxidized serves as the first electrode portion 40. The insulating film 60A present between the first electrode portion 40 and the inside wall of the trench T5 serves as the first insulating portion 60.

By the oxidation processing described above, the space R11 serves as a space R12 that is slightly smaller than the space R11.

Then, as shown in FIG. 19F, the second electrode portion 50 is formed in the space R2 surrounded by the second insulating portion 70. For example, a polysilicon is used as the second electrode portion 50. The third electrode portion 65 shown in FIG. 11A is formed in the same process as the second electrode portion 50. By the processes described above, the structure within the trench is completed.

In the manufacturing method shown in FIGS. 19A to 19F, since the first electrode film 40A in the portion of the trench T5 of the width w2 is removed by, for example, CDE and is then oxidized, and the second insulating portion 70 is formed, it is possible to reduce the thickness of the second insulating portion 70 as compared with the manufacturing method shown in FIGS. 18A to 183. In this way, the width of the trench T5 along the Y-axis direction is reduced, and thus it is possible to obtain a merit of reducing the trench pitch.

Here, in order for the structure within the trench shown in FIG. 10A to be formed in the manufacturing method illustrated in FIGS. 18A to 183 or FIGS. 19A to 19F, when the first conductive portion material 10A shown in FIG. 5C is embedded in a trench T4, arsenic (As) or P is added as an impurity to the first conductive portion material 10A. In this way, when the insulating film 60A is formed in the process shown in FIG. 18B or FIG. 19B, the insulating film 60A in contact with the first conductive portion material 10A is rapidly oxidized, and thus it is possible to increase the thickness of the third insulting portion 80 as compared with the first insulating portion 60.

For example, when an impurity concentration is set at 5×10¹⁹ atm/cm³, if P is used as an impurity, it is possible to form the third insulting portion 80 that is several tens of percent as thick as the first insulating portion 60. When As is used as an impurity at the same impurity concentration, it is possible to form the third insulting portion 80 that is about 200% as thick as the first insulating portion 60. When the thickness of the third insulting portion 80 is increased, this effectively reduces the gate capacitance. Therefore, it is preferable to use As as the impurity.

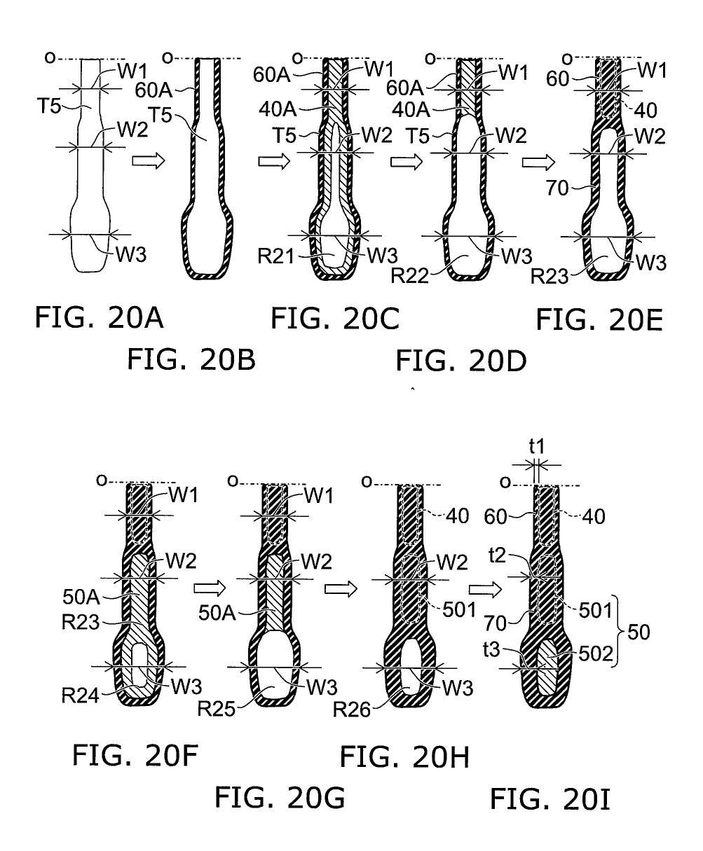

FIGS. 20A to 20I are schematic views illustrating the method (a third method) of manufacturing the structure within the trench.

FIGS. 20A to 20I show schematic plan views of the Z1 portion shown in FIG. 1 in order of the processes. For ease of description, only the state of the interior of the trench T5 will be illustrated.

The manufacturing method shown in FIGS. 20A to 20I is an example of the method of manufacturing the structure within the trench shown in FIG. 12A.

First, as shown in FIG. 20A, the trench T5 is formed. The width along the Y-axis direction of the opening, as viewed in the Z-axis direction, of the trench T5 serves as the width w1, the width w2 and then the width w3. The width sequentially becomes greater as it serves as the width w1, the width w2 and then the width w3. The width becomes gradually greater from the portion of the trench T5 of the width w1 to the portion of the width w2. The width becomes gradually greater from the portion of the width w2 to the portion of the width w3.

Then, as shown in FIG. 20B, the insulating film 60A is formed on the inside wall of the trench T5. The insulating film 60A is, for example, a thermal oxide film of silicon. Then, as shown in FIG. 20C, the first electrode film 40A is formed on the insulating film 60A within the trench T5. The first electrode film 40A is, for example, a polysilicon containing an impurity. The first electrode film 40A is deposited on the insulating film 60A.

Here, the first electrode film 40A is embedded in the portion of the trench T5 of the width w1, and is formed such that a space R21 is left on the portion of the trench T5 of the width w2 and the portion of the width w3. That is, the first electrode film 40A is embedded in the portion (the portion of the width w1) of the trench T5 of a narrow width, whereas the first electrode film 40A is incompletely embedded in the portions (the portions of the widths w2 and w3) of the trench T5 of a wide width.

Next, as shown in FIG. 20D, the first electrode film 40A provided in the portion of the trench T5 of the width w2 and the portion of the width w3 is removed. The first electrode film 40A is removed by, for example, CDE. Therefore, a space R22 is provided in the portion of the trench T5 of the width w2 and the portion of the width w3.

Then, as shown in FIG. 20E, a portion of the first electrode film 40A is oxidized. That is, when, for example, a polysilicon is used as the first electrode film 40A, oxidation processing is performed under an atmosphere of oxygen, and the portion is changed into a silicon oxide film. The oxidation of the first electrode film 40A progresses from a portion exposed to the space R22 and the upper face (exposed portion) of the portion of the width w1. When the first electrode film 40A is not left in the portions of the trench T5 of the width w2 and the width w3, the thickness of the insulating film 60A is increased.

By the oxidation described above, the first electrode film 40A in the portion of the width w2 serves as the second insulating portion 70. In contrast, although the portion of the width w1 is oxidized from the upper face (the exposed portion) to a portion of the interior, a portion that is left without being oxidized serves as the first electrode portion 40. The insulating film 60A present between the first electrode portion 40 and the inside wall of the trench T5 serves as the first insulating portion 60. By the oxidation processing described above, the space R22 serves as a space R23 that is slightly smaller than the space R22.

Next, as shown in FIG. 20F, a second electrode film 50A is formed in the space R2 surrounded by the second insulating portion 70. For example, a polysilicon is used as the second electrode film 50A. The second electrode film 50A is embedded in the portion of the trench T5 of the width w2, and is formed such that a space R24 is left in the portion of the trench T5 of the width w3.

Then, as shown in FIG. 20G, the second electrode film 50A provided in the portion of the trench T5 of the width w3 is removed. The second electrode film 50A is removed by, for example, CDE. Therefore, a space R25 is provided in the portion of the trench T5 of the width w3.

Then, as shown in FIG. 20H, a portion of the second electrode film 50A is oxidized. That is, when, for example, a polysilicon is used as the fifth electrode film 50A, oxidation processing is performed under an atmosphere of oxygen, and the portion is changed into a silicon oxide film. The oxidation of the fifth electrode film 50A progresses from a portion exposed to the space R25 and the upper face (exposed portion) of the portion of the width w2. When the second electrode film 50A is not left in the portion of the trench T5 of the width w3, the thickness of the insulating film 60A is increased.

By the oxidation described above, the second insulating portion 70 is formed in the portion of the width w3. In contrast, although the portion of the width w2 is oxidized from the upper face (the exposed portion) to a portion of the interior, a portion that is left without being oxidized serves as the sub-electrode portion 501 of the second electrode portion 50.

By the oxidation processing described above, the space R25 serves as a space R26 that is slightly smaller than the space R25.

Then, as shown in FIG. 20I, the sub-electrode portion 502 of the second electrode portion 50 is formed in the space R26 surrounded by the second insulating portion 70. For example, a polysilicon is used as the sub-electrode portion 502. By the processes described above, the structure within the trench is completed.

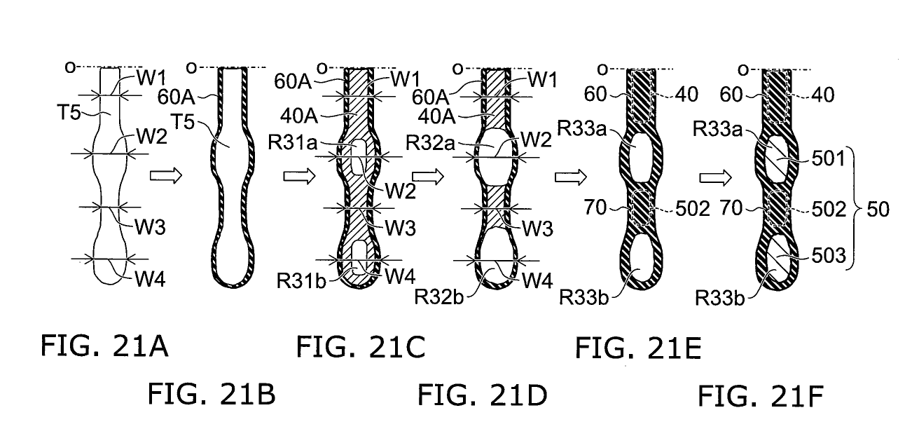

FIGS. 21A to 21F are schematic views illustrating the method (a fourth method) of manufacturing the structure within the trench.

FIGS. 21A to 21F show schematic plan views of the Z1 portion shown in FIG. 1 in order of the processes. For ease of description, only the state of the interior of the trench T5 will be illustrated.

The manufacturing method shown in FIGS. 21A to 21F is an example of the method of manufacturing the structure within the trench shown in FIG. 13A.

First, as shown in FIG. 21A, the trench T5 is formed. The width along the Y-axis direction of the opening, as viewed in the Z-axis direction, of the trench T5 serves as the width w1, the width w2, the width w3 and then a width w4. The width alternately becomes narrow and great as it serves as the width w1, the width w2, the width w3 and then the width w4. The width becomes gradually greater from the portion of the trench T5 of the width w1 to the portion of the width w2. The width becomes gradually narrower from the portion of the width w2 to the portion of the width w3. The width becomes gradually greater from the portion of the width w3 to the portion of the width w4.

Next, as shown in FIG. 21B, the insulating film 60A is formed on the inside wall of the trench T5. The insulating film 60A is, for example, a thermal oxide film of silicon. Then, as shown in FIG. 21C, the first electrode film 40A is formed on the insulating film 60A within the trench T5. The first electrode film 40A is, for example, a polysilicon containing an impurity. The first electrode film 40A is deposited on the insulating film 60A.

Here, the first electrode film 40A is embedded in the portion of the trench T5 of the width w1 and the portion of the width w3, and is formed such that spaces R31a and R31b are left on the portion of the trench T5 of the width w2 and the portion of the width w4. That is, the first electrode film 40A is embedded in the portion (the portions of the widths w1 and w3) of the trench T5 of a narrow width, whereas the first electrode film 40A is incompletely embedded in the portions (the portions of the widths w2 and w3) of the trench T5 of a wide width.

Then, as shown in FIG. 21D, the first electrode film 40A provided in the portion of the trench T5 of the width w2 and the portion of the width w4 is removed. The first electrode film 40A is removed by, for example, CDE. Therefore, spaces R32a and R32b are provided in the portion of the trench T5 of the width w2 and the portion of the width w4.

Then, as shown in FIG. 21E, a portion of the first electrode film 40A is oxidized. That is, when, for example, a polysilicon is used as the first electrode film 40A, oxidation processing is performed under an atmosphere of oxygen, and the portion is changed into a silicon oxide film. The oxidation of the first electrode film 40A progresses from a portion exposed to the spaces R32a and R32b and the upper face (exposed portion) of the portion of the width w1 and the portion of the width w3. When the first electrode film 40A is not left in the portion of the trench T5 of the width w2 and the portion of the width w4, the thickness of the insulating film 60A is increased.

By the oxidation described above, the first electrode film 40A in the portions of the width w2, the width w3 and the width w4 serves as the second insulating portion 70. In contrast, although the portion of the width w1 is oxidized from the upper face (the exposed portion) to a portion of the interior, a portion that is left without being oxidized serves as the first electrode portion 40.

The insulating film 60A present between the first electrode portion 40 and the inside wall of the trench T5 serves as the first insulating portion 60. In contrast, although the portion of the width w3 is oxidized from the upper face (the exposed portion) to a portion of the interior, a portion that is left without being oxidized serves as the sub-electrode portion 502 of the second electrode portion 50.

By the oxidation described above, the space R32a and R32b serves as spaces R33a and R33b that are slightly smaller than the space R32a and R32b.

Then, as shown in FIG. 21F, the sub-electrode portions 501 and 503 of the second electrode portion 50 are formed in the spaces R33a and R33b surrounded by the second insulating portion 70. For example, a polysilicon is used as the sub-electrode portions 501 and 503. By the processes described above, the structure within the trench is completed.

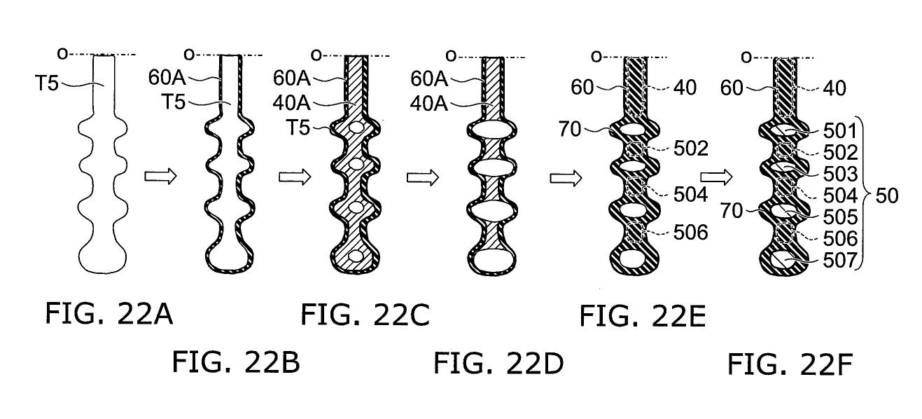

FIGS. 22A to 20F are schematic views illustrating the method (a fifth method) of manufacturing the structure within the trench.

FIGS. 22A to 22F show schematic plan views of the Z1 portion shown in FIG. 1 in order of the processes. For ease of description, only the state of the interior of the trench T5 will be illustrated.

The manufacturing method shown in FIGS. 22A to 22F is an example of the method of manufacturing the structure within the trench shown in FIG. 14A.

The method of manufacturing the structure within the trench illustrated in FIGS. 22A to 22F differs from the method of manufacturing the structure within the trench illustrated in FIGS. 21A to 21F in that the number of times the width of the trench T5 becomes great and narrow is increased. The other processes are the same. That is, in the method of manufacturing the structure within the trench shown in FIG. 14A, the shape of the opening of the trench T5 shown in FIG. 21A and seen in the Z-axis direction is preferably changed into the shape of the opening of the trench T5 shown in FIG. 22A and seen in the Z-axis direction. The processes illustrated in FIGS. 22B to 22F are the same as those illustrated in FIGS. 21B to 21F.

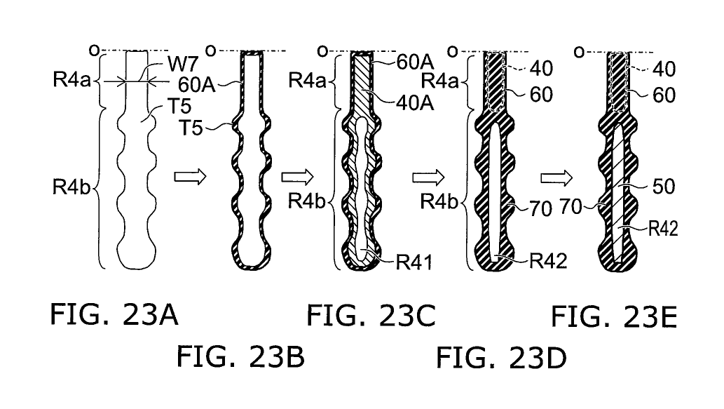

FIGS. 23A to 23E are schematic views illustrating the method (a sixth method) of manufacturing the structure within the trench.

FIGS. 23A to 23E show schematic plan views of the Z1 portion shown in FIG. 1 in order of the processes. For ease of description, only the state of the interior of the trench T5 will be illustrated.

The manufacturing method shown in FIGS. 23A to 23E is an example of the method of manufacturing the structure within the trench shown in FIG. 15A.

First, as shown in FIG. 23A, the trench T5 is formed. The shape of the opening of the trench T5 as viewed in the Z-axis direction has a portion R4a having an approximately constant width of w1 along the Y-axis direction and a portion R4b having a repeated, large and narrow width. Next, as shown in FIG. 23B, the insulating film 60A is formed on the inside wall of the trench T5. The insulating film 60A is, for example, a thermal oxide film of silicon.

Next, as shown in FIG. 23C, the first electrode film 40A is formed on the insulating film 60A within the trench T5. The first electrode film 40A is, for example, a polysilicon containing an impurity. The first electrode film 40A is deposited on the insulating film 60A.

Here, the first electrode film 40A is embedded in the portion R4a of the trench T5 of the width w1, and is formed such that a space R41 is left on the portion R4b having a large and narrow width. That is, the first electrode film 40A is embedded in the portion (the portion R4a of the width w1) of the trench T5 having a narrow width, whereas the first electrode film 40A is incompletely embedded in the portion R4b having a repeated, large and narrow width of the trench T5. The space R41 is provided to communicate along the X-axis direction.

Then, as shown in FIG. 23D, a portion of the first electrode film 40A is oxidized. That is, when, for example, a polysilicon is used as the first electrode film 40A, oxidation processing is performed under an atmosphere of oxygen, and the portion is changed into a silicon oxide film. The oxidation of the first electrode film 40A progresses from a portion exposed to the space R41 and the upper face (exposed portion) of the portion R4a of the width w1.

By the oxidation described above, the second insulating portion 70 is formed in the portion R4b. In contrast, although the portion R4b is oxidized from the upper face (the exposed portion) up to a portion of the interior, a portion that is left without being oxidized serves as the first electrode portion 40. The insulating film 60A present between the first electrode portion 40 and the inside wall of the trench T5 serves as the first insulating portion 60.

By the oxidation processing described above, the space R41 serves as a space R42 that is slightly smaller than the space R41.

Then, as shown in FIG. 23E, the second electrode portion 50 is formed in the space R42 surrounded by the second insulating portion 70. For example, a polysilicon is used as the second electrode portion 50. By the processes described above, the structure within the trench is completed.

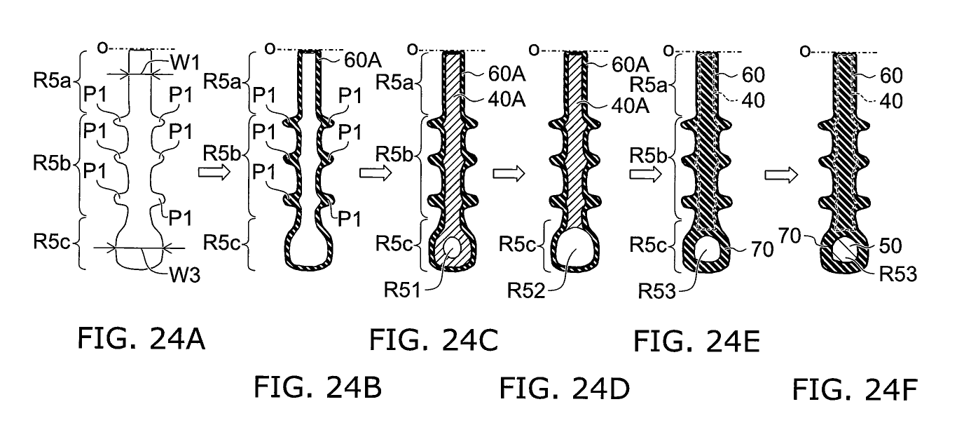

FIGS. 24A to 24F are schematic views illustrating the method (a seventh method) of manufacturing the structure within the trench.

FIGS. 24A to 24F show schematic plan views of the Z1 portion shown in FIG. 1 in order of the processes. For ease of description, only the state of the interior of the trench T5 will be illustrated.

The manufacturing method shown in FIGS. 24A to 24F is an example of the method of manufacturing the structure within the trench shown in FIG. 16A.

First, as shown in FIG. 24A, the trench T5 is formed. The shape of the opening of the trench T5 as viewed in the Z-axis direction has a portion R5a having an approximately constant width of w1 along the Y-axis direction, a portion R5b having a repeated, large and narrow width and a portion R5c having the width w3. The width w3 is greater than the width w1. In the portion R5b, a recess portion P1 is provided in the portion having a narrow width of the trench T5. Then, as shown in FIG. 24B, the insulating film 60A is formed on the inside wall of the trench T5. The insulating film 60A is, for example, a thermal oxide film of silicon. The insulating film 60A is embedded in the recess portion P1.

Next, as shown in FIG. 24C, the first electrode film 40A is formed on the insulating film 60A within the trench T5. The first electrode film 40A is, for example, a polysilicon containing an impurity. The first electrode film 40A is deposited on the insulating film 60A.

Here, the first electrode film 40A is embedded in the portions R5a and R5b of the trench T5, and is formed such that a space R51 is left on the portion R5c of the trench T5. That is, the first electrode film 40A is embedded in the portion (the portion R5a of the width w1) of the trench T5 of a narrow width and the portion R5b having a repeated, large and narrow width, whereas the first electrode film 40A is incompletely embedded in the portion (the portion R5c of the width w3) of the trench T5 of a wide width.

Then, as shown in FIG. 24D, the first electrode film 40A provided in the portion R5c of the trench T5 is removed. The first electrode film 40A is removed by, for example, CDE. Thus, a space R52 is provided in the portion R5c of the trench T5.

Next, as shown in FIG. 24E, a portion of the first electrode film 40A is oxidized. That is, when, for example, a polysilicon is used as the first electrode film 40A, oxidation processing is performed under an atmosphere of oxygen, and the portion is changed into a silicon oxide film. The oxidation of the first electrode film 40A progresses from a portion exposed to the space R52 and the upper face (exposed portion) of the portions R5a and R5b. When the first electrode film 40A is not left in the portion R5c of the trench T5, the thickness of the insulating film 60A is increased.

By the oxidation described above, the second insulating portion 70 is formed in the portion R5c of the trench T5. In contrast, although the portions Rya and R5b of the trench T5 are oxidized from the upper face (the exposed portion) to a portion of the interior, a portion that is left without being oxidized serves as the first electrode portion 40. The insulating film 60A present between the first electrode portion 40 and the inside wall of the trench T5 serves as the first insulating portion 60.

By the oxidation processing described above, the space R52 serves as a space R53 that is slightly smaller than the space R52.

Then, as shown in FIG. 24F, the second electrode portion 50 is formed in the space R53 surrounded by the second insulating portion 70. For example, a polysilicon is used as the second electrode portion 50. By the processes described above, the structure within the trench is completed.

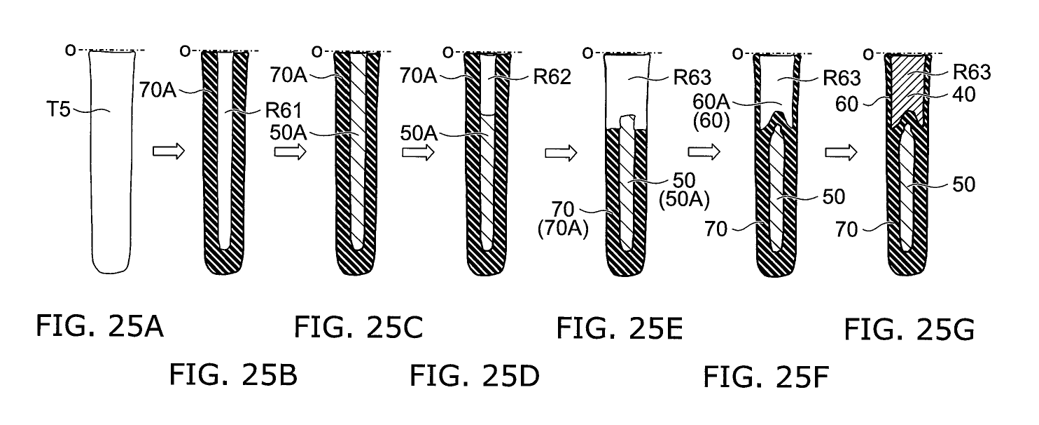

FIGS. 25A to 25G are schematic views illustrating the method (an eighth method) of manufacturing the structure within the trench.

FIGS. 25A to 25G show schematic plan views of the Z1 portion shown in FIG. 1 in order of the processes. For ease of description, only the state of the interior of the trench T5 will be illustrated.

The manufacturing method shown in FIGS. 25A to 25G is an example of the method of manufacturing the structure within the trench shown in FIG. 17A.

First, as shown in FIG. 25A, the trench T5 (a third trench) is formed. The width along the Y-axis direction of the opening of the trench T5 as viewed in the Z-axis direction is substantially constant. Then, as shown in FIG. 25B, an insulating film 70A is formed on the inside wall of the trench T5. The insulating film 70A is, for example, a thermal oxide film of silicon. Within the trench T5, a space R61 that is left without the insulating film 70A being formed is provided. The space R61 extends along the X-axis direction.

Then, as shown in FIG. 25C, the second electrode film 50A is formed in the space R61 within the trench T5. For example, a polysilicon is used as the second electrode film 50A. The second electrode film 50A is embedded within the space R61.

Then, as shown in FIG. 25D, a portion of the second electrode film 50A on the side opposite to the second conductive portion 20 is removed. The second electrode film 50A is selectively etched by dry etching such as RIE. Thus, in the trench T5, the portion of the second electrode film 50A is removed, and a space R62 is provided. The second electrode film 50A that is left within the trench T5 serves as the second electrode portion 50.

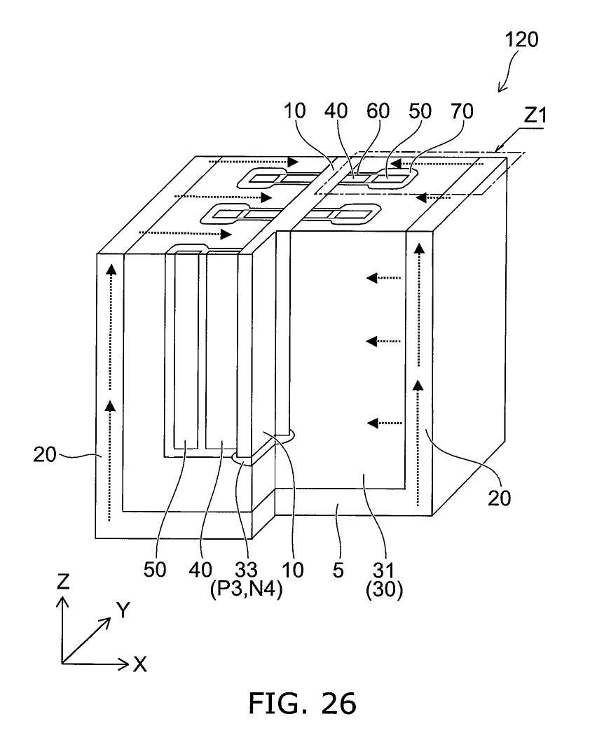

Then, as shown in FIG. 25E, a portion of the insulating film 70A within the trench T5 is removed. The insulating film 70A is removed by, for example, wet etching. Thus, a space R63 is formed within the trench T5. The insulating film 70A is removed until an end portion of the second electrode portion 50 is exposed. The insulating film 70A provided between the second electrode portion 50 and the inside wall of the trench T5 serves as the second insulating portion 70. Although, in the state illustrated in FIG. 26E, the end portion of the second electrode portion 50 protrudes to the side of the space R63, it may not protrude.

Then, as shown in FIG. 25F, the insulating film 60A is formed on the inside wall of the trench T5 in the space R63. The insulating film 60A is, for example, a thermal oxide film of silicon. The insulating film 60A is formed not only on the inside wall of the trench T5 but also on the end face of the second insulating portion 70 on the side of the space R63 and on the end face of the second electrode portion 50 on the side of the space R63. The insulating film 60A formed on the inside wall of the trench T5 exposed to the space R63 serves as the first insulating portion 60.

Here, since, when the insulating film 60A is formed, an impurity is included in the second electrode portion 50, the end face of the second electrode portion 50 on the side of the space R62 has a high oxidation rate, and the insulating film 60A thicker than the inside wall of the trench T5 is formed. When the insulating film 60A is provided on the end face of the second electrode portion 50 on the side of the space R62 such that the insulating film 60A has a great thickness, this is effective for reducing the gate capacitance.

Then, as shown in FIG. 25G, the first electrode portion 40 is formed in the space R63 within the trench T5. The first electrode film 40A is, for example, a polysilicon containing an impurity. By the processes described above, the structure within the trench is completed.

### Second Embodiment

FIG. 26 is a schematic perspective view illustrating the configuration of a semiconductor device according to a second embodiment.

FIG. 26 shows a partially exploded schematic perspective view of a semiconductor device 120. The semiconductor device 120 illustrated in FIG. 26 is a Schottky barrier diode (hereinafter simply referred to as an “SBD”). In FIG. 26, for ease of description, only part of the semiconductor device 120 is shown.

The semiconductor device 120 includes the substrate 5, the first conductive portion 10, the second conductive portion 20, the semiconductor portion 30, the first electrode portion 40, the second electrode portion 50, the first insulating portion 60 and the second insulating portion 70.

In the semiconductor device 120, as the substrate 5, for example, an n⁺ semiconductor substrate is used. The semiconductor substrate is, for example, a silicon wafer.

On the substrate 5, the first conductive portion 10 is provided so as to extend in the Z-axis direction. In the semiconductor device 120 shown in FIG. 26, the first conductive portion 10 is a Schottky barrier metal. As the first conductive portion 10, a stacked film is used that is, for example, a stacked film of W (tungsten)-Al (aluminum), a stacked film of W—Ni (nickel)-Au or a stacked film obtained by using, instead of W of these stacked films, Mo (molybdenum), Pt (platinum), TiW (titanium-tungsten alloy), V (vanadium), Ti (titanium) or the like.

On the substrate 5, the second conductive portion 20 is provided so as to extend in the Z-axis direction. The second conductive portion 20 is provided to be separated from the first conductive portion 10 along the X-axis direction. In the semiconductor device 120 shown in FIG. 1, the second conductive portion 20 is an n⁺ pillar portion that rises from the major surface 5a of the substrate 5 in the Z-axis direction. The ⁺pillar portion functions as, for example, a cathode of the SBD. The substrate 5 in electrical conduction with the second conductive portion 20 functions as a cathode electrode of the SBD.

The semiconductor portion 30 is provided between the first conductive portion 10 and the second conductive portion 20. The semiconductor portion 30 is embedded between the first conductive portion 10 and the second conductive portion 20 extending in the Z-axis direction. The semiconductor portion 30 includes the n-type first semiconductor region 31 of the first impurity concentration. The first semiconductor region 31 is the n-type drift region. The first semiconductor region 31 is Schottky-junctioned to the first conductive portion 10.

The first electrode portion 40 is provided between the first conductive portion 10 and the second conductive portion 20 so as to extend in the Z-axis direction. The first electrode portion 40 is in electrical conduction with the first conductive portion 10. That is, the first electrode portion 40 has the same potential as the first conductive portion 10 that is the Schottky barrier metal. The first electrode portion 40 is formed from the first conductive portion 10 along the X-axis direction so as to extend midway through the first semiconductor region 31.

The second electrode portion 50 is provided between the first electrode portion 40 and the second conductive portion 20 so as to extend in the Z-axis direction. The second electrode portion 50 is provided to be separated from the first electrode portion 40. The second electrode portion 50 is provided within the first semiconductor region 31 between the first electrode portion 40 and the second conductive portion 20.

The first insulating portion 60 is provided between the first electrode portion 40 and the semiconductor portion 30. The first insulating portion 60 has the first thickness t1 in the normal direction of the boundary face of the first electrode portion 40. In the semiconductor device 120, the first electrode portion 40, the first insulating portion 60 and the semiconductor portion 30 constitute a MOS structure. That is, the semiconductor device 120 is a trench MOS barrier Schottky (TMBS) in which the MOS structure is provided on a Schottky barrier face (a contact face between the first conductive portion 10 and the semiconductor portion 30 (the first semiconductor region 31).

The second insulating portion 70 is provided between the second electrode portion 50 and the semiconductor portion 30. The second insulating portion 70 has the second thickness t2 greater than the first thickness t1 in the normal direction of the boundary face of the second electrode portion 50.

The semiconductor device 120 includes at least one each of the first conductive portion 10, the second conductive portion 20, the semiconductor portion 30, the first electrode portion 40, the second electrode portion 50, the first insulating portion 60 and the second insulating portion 70.

In the semiconductor device 120 shown in FIG. 26, one first conductive portion 10 (the Schottky barrier metal) also extends in the Y-axis direction, and the second conductive portions 20 (the n⁺ pillar portions) are provided both on one side of and the other side of the X-axis direction with the first conductive portion 10 in the center therebetween. The first electrode portion 40 and the second electrode portion 50 are line-symmetrically provided with respect to the first conductive portion 10. A plurality of groups, each composed of the first electrode portion 40 and the second electrode portion 50 provided line-symmetrically, are spaced a predetermined distance apart along the Y-axis direction.

Arrows shown in FIG. 26 represent the flow of electrons. In the semiconductor device 120, when a high voltage (a positive potential) as compared with the second conductive portion 20 is applied to the first conductive portion 10 (the Schottky barrier metal), the electrons pass through the semiconductor portion 30 (the first semiconductor region 31) from the second conductive portion 20, and flow to the first conductive portion 10.

In the semiconductor device 120, the area of the Schottky barrier face can be increased, the impurity concentration in the first semiconductor region 31 can be reduced, and high breakdown voltage can be obtained. Since the semiconductor device 120 has the FP structure, it is possible to reduce a VF (forward drop voltage).

In the semiconductor device 120, the electric field alleviation region 33 may be formed in the semiconductor portion 30 on the side of the first conductive portion 10 between the substrate 5 and the first conductive portion 10.

As the electric field alleviation region 33, a third concentration region P3 of a p-type semiconductor (silicon) or a fourth concentration region N4 of an n⁻ semiconductor (silicon) higher in resistivity than the first semiconductor region 31 is used. The electric field alleviation region 33 is provided, and thus it is possible to alleviate the concentration of the electric filed at the end portion of the first conductive portion 10 on the side of the substrate 5 and to enhance the breakdown voltage. Since it is possible to eliminate the Schottky barrier face in the portion in which the electric field alleviation region 33 is provided, it is possible to reduce a leak current.

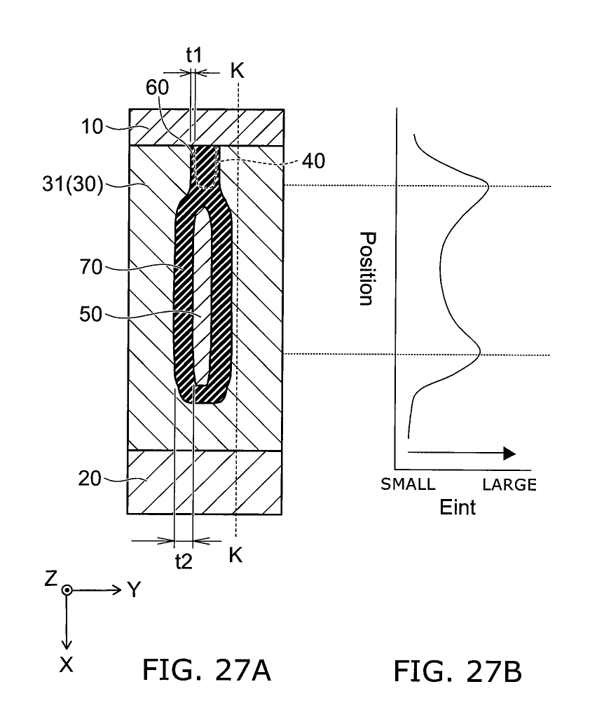

FIGS. 27A and 27B are schematic views illustrating a cross section and an electric field strength distribution.

FIG. 27A is a schematic plan view of the Z1 portion shown in FIG. 26 as viewed in the Z-axis direction. FIG. 27A shows the first electrode portion 40 and the second electrode portion 50 on one side with the first conductive portion 10 in the center. FIG. 27B illustrates the electric field strength distribution in a position along line K-K shown in FIG. 27A. In FIG. 27B, the axis of “Position” represents the position along line K-K, and the axis of “Eint” represents the electric field strength distribution.

As shown in FIG. 27A, the first insulating portion 60 having the first thickness t1 is provided between the first electrode portion 40 and the second semiconductor region 32. The second insulating portion 70 having the second thickness t2 is provided between the second electrode portion 50 and the first semiconductor region 31. The second thickness t2 is greater than the first thickness t1.

As described above, the second thickness t2 of the second insulating portion 70 is greater than the first thickness t1 of the first insulating portion 60, and thus the FP structure that alleviates the concentration of the electric filed at the end portion of the first electrode portion 40 on the side of the second conductive portion 20 is realized. In this way, as compared with a structure having no FP structure, the leak current is reduced. That is, since the first thickness t1 of the first insulating portion 60 is smaller than the second thickness t2 of the second insulating portion 70, a depletion layer easily extends in a reverse bias. Thus, it is possible to reduce the leak current.

A method of manufacturing the semiconductor device 120 will now be described.

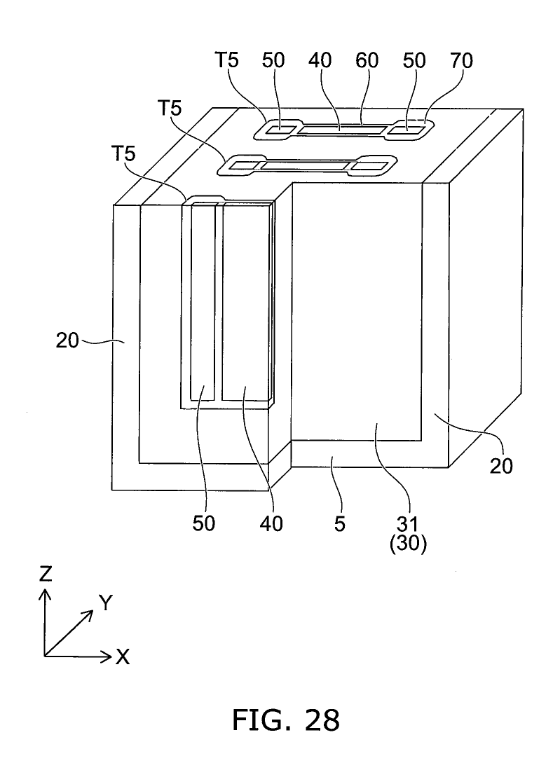

FIGS. 28 to 30 are schematic perspective views illustrating the method of manufacturing the semiconductor device.

First, in any one of the processes shown in FIGS. 3A to 3D or FIGS. 4A to 4D, the substrate 5, the second conductive portion 20 and the semiconductor portion 30 (the first semiconductor region 31) are formed.

Next, as shown in FIG. 28, on the semiconductor portion 30 (the first semiconductor region 31), the first electrode portion 40, the second electrode portion 50, the first insulating portion 60 and the second insulating portion 70 are formed. The processes illustrated in FIGS. 6 to 8 are applied to the method of forming these portions.

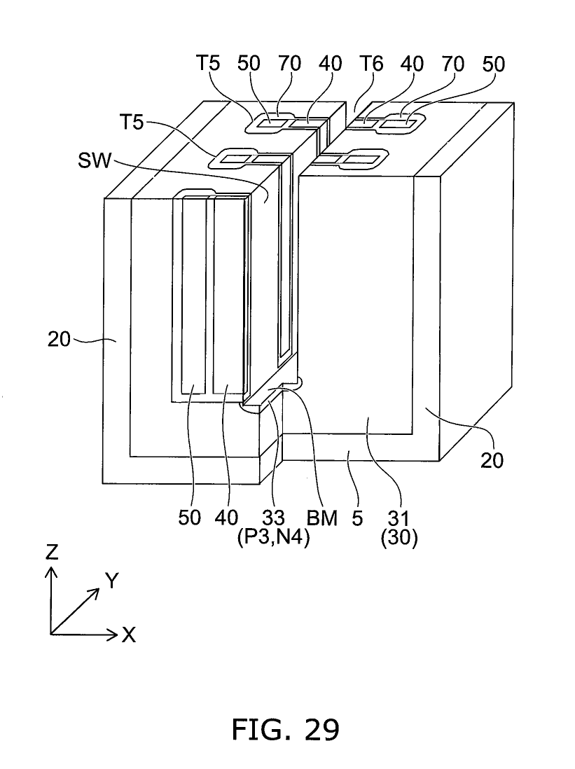

Then, as shown in FIG. 29, a trench T6 (a second trench) is formed in the semiconductor portion 30 (the first semiconductor region 31). The trench T6 is formed in the center portion of the opposite second conductive portion 20 so as to extend in the Y-axis direction. The first electrode portion 40 and the first insulating portion 60 are divided by the trench T6. The depth of the trench T6 along the Z-axis direction is greater than the depth of the first insulating portion 60 and the second insulating portion 70 along the Z-axis direction, and the trench T6 is provided midway through the semiconductor portion 30 (the first semiconductor region 31). The semiconductor portion 30 (the first semiconductor region 31) is exposed to the bottom portion BM of the trench T6.

Then, an impurity is implanted into the bottom portion BM of the trench T6, and thus the electric field alleviation region 33 is formed. For example, boron (B) is ion-implanted obliquely into the bottom portion BM of the trench T6, and is thermally diffused. The electric field alleviation region 33 formed by the ion implantation of B and the thermal diffusion is the fourth concentration region N4 of an n⁻ type semiconductor that is lower in impurity concentration than the third concentration region P3 or the semiconductor portion 30 (the first semiconductor region 31).

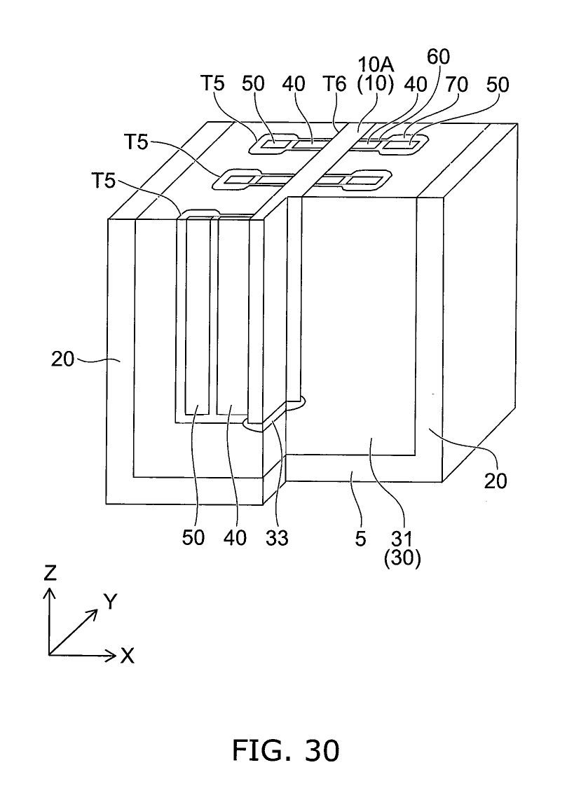

Then, as shown in FIG. 30, the first conductive portion material portion 10A is embedded within the trench T6. The first conductive portion material 10A is a stacked film that makes use of, for example, a single layer of W, a stacked film of W—Al or a stacked film obtained by using, instead of W of these stacked films, Mo, Pt, TiW, V, Ti or the like. The stacked film used as the first conductive portion material 10A may be a silicide layer that is an alloy with silicon. The first conductive portion material 10A embedded within the trench T6 is changed, by sintering processing, to become the first conductive portion 10 that is Schottky-junctioned to the semiconductor portion 30 (the first semiconductor region 31).

In this way, the semiconductor device 120 is completed.

Variations of the semiconductor device 120 will now be described.

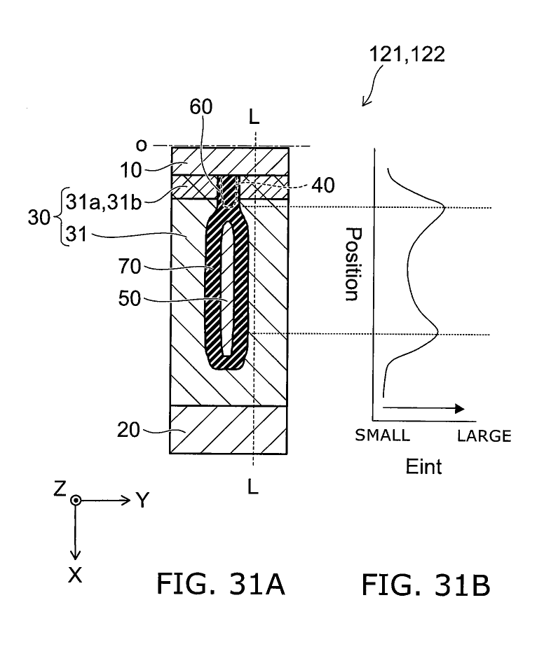

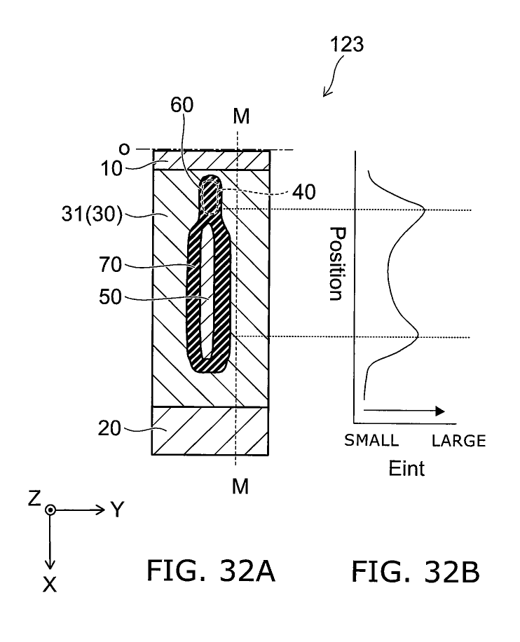

FIGS. 31A to 32B are diagrams illustrating the variations of the semiconductor device.

In FIGS. 31A and 31B and FIGS. 32A and 32B, FIGS. 31A and 32A are schematic plan views of the Z1 portion shown in FIG. 26, and FIGS. 31B and 32B illustrate an electric field strength distribution in a position along a line shown in FIGS. 31A and 32A. In those figures, FIGS. 31A and 32A show the first electrode portion 40 and the second electrode portion 50 on one side with the first conductive portion 10 in the center. Therefore, when a combination of the first electrode portion 40 and the second electrode portion 50 is line-symmetrically provided with respect to the first conductive portion 10, portions obtained by reversing the individual portions shown in FIGS. 31A and 32A with respect to an alternate long and short dashed line o in the figures are formed. In the following description, for ease of description, only a combination of the first electrode portion 40 and the second electrode portion 50 on one side with the first conductive portion 10 in the center will be illustrated.

In a semiconductor device 121 according to the variation shown in FIG. 31A, the semiconductor portion 30 on the side of the first conductive portion 10 includes a first concentration region 31a of an impurity concentration lower than the impurity concentration (the first impurity concentration) of the first semiconductor region 31. That is, the first concentration region 31a is an n⁻ semiconductor region.

FIG. 31B illustrates an electric field strength distribution in a position along line L-L shown in FIG. 31A. In FIG. 31B, the axis of “Position” represents the position along line L-L, and the axis of “Eint” represents the electric field strength distribution.

In order to form the first concentration region 31a, in the process shown in FIG. 29, B is ion-implanted into a side wall SW of the trench T6, and is thermally diffused. Therefore, the first concentration region 31a lower in impurity concentration than the first semiconductor region 31 is formed.

In the semiconductor device 121, the first concentration region 31a is provided on the Schottky barrier face of the semiconductor portion 30, and thus it is possible to prevent φB (work function) from being lowered due to Schottky barrier lowing effects. Since a depletion layer easily extends on the Schottky barrier face, it is possible to alleviate the concentration of the electric field and reduce the leak current.

In a semiconductor device 122 according to another variation shown in FIGS. 31A and 31B, the semiconductor portion 30 on the side of the first conductive portion 10 includes a second concentration region 31b of an impurity concentration higher than the impurity concentration (the first impurity concentration) of the first semiconductor region 31. That is, the second concentration region 31b is an n⁺ semiconductor region.

In order to form the second concentration region 31b, in the process shown in FIG. 29, As or P is ion-implanted into the side wall SW of the trench T6, and is thermally diffused. Therefore, the second concentration region 31b higher in impurity concentration than the first semiconductor region 31 is formed.

In the semiconductor device 122, the second concentration region 31b higher in impurity concentration than the first semiconductor region 31 is formed in a region of the semiconductor portion 30 in contact with the first conductive portion 10 that is a Schottky barrier metal, and thus it is possible to reduce the decrease in VF.

In a semiconductor device 123 according to a variation shown in FIG. 32, the first electrode portion 40 is formed to be separated from the boundary face between the first conductive portion 10 and the semiconductor portion 30 in the X-axis direction.

In order for this semiconductor device 123 to be manufactured, when, in the process shown in FIG. 28, the trench T5 (see FIG. 6) is formed, it is provided to be divided into a portion on one side and a portion on the other side in the X-axis direction with the formation position of the first conductive portion 10 in the center.

FIG. 32B illustrates an electric field strength distribution in a position along line M-M shown in FIG. 32A. In FIG. 32B, the axis of “Position” represents the position along line M-M, and the axis of “Eint” represents the electric field strength distribution.

In the semiconductor device 123, as compared with the semiconductor devices 120, 121 and 122, the area of the Schottky barrier face that is the contact face between the first conductive portion 10 and the semiconductor portion 30 can be increased, and thus it is possible to reduce the VF.

In the semiconductor device 123, when the trench T6 (see FIG. 29) is formed, a target to be etched is only the semiconductor portion 30. Since the same material is etched, etching conditions can easily be set.

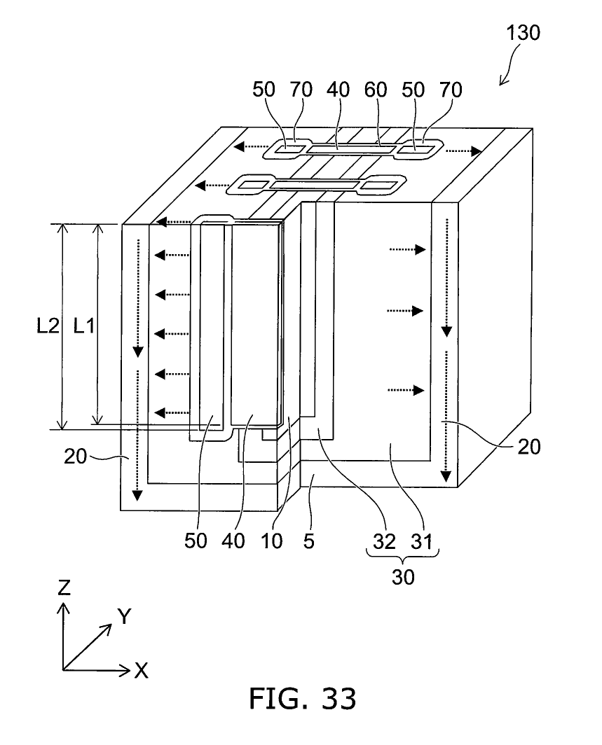

FIG. 33 is a schematic perspective view illustrating another example of the second electrode portion.

Although FIG. 33 shows an example of the MOSFET, the same is true for the SBD.

As shown in FIG. 33, in a semiconductor device 130, the length L2 of the second electrode portion 50 along the Z-axis direction is greater than the length L1 of the first electrode portion 40 along the Z-axis direction.

In order for the second electrode portion 50 described above to be formed, a difference in an etching rate when the trench T5 is formed is utilized. That is, when the trench T5 is formed, as compared with a portion having a narrow width along the Y-axis direction, in a portion having a wide width, the depth of etching along the Z-axis direction in isotropic ion etching is greater. By actively utilizing this phenomenon, the depth of the trench T5 in a portion in which the second electrode portion 50 is formed is made greater than the depth of the trench T5 of a portion in which the first electrode portion 40 is formed. In this way, the length L2 of the second electrode portion 50 along the Z-axis direction is greater than the length L1 of the first electrode portion 40 along the Z-axis direction.

In the structure described above, the portion of the second insulating portion 70 on the side of the substrate 5 surrounds the portion of the first insulating portion 60 on the side of the substrate 5. Because of this, it is possible to improve the decrease in breakdown voltage on the bottom portion of the trench structure and to reduce the capacitance.

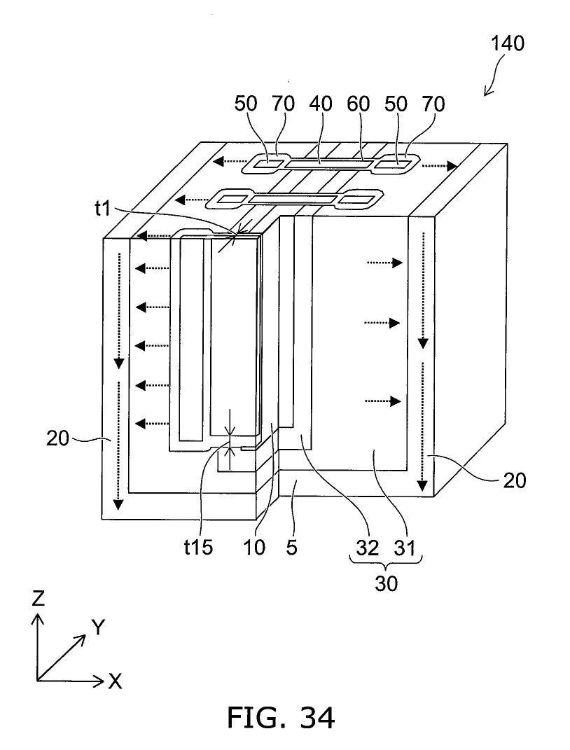

FIG. 34 is a schematic perspective view illustrating another example of the first insulating portion.

Although FIG. 34 shows an example of the MOSFET, the same is true for the SBD.

As shown in FIG. 33, in a semiconductor device 140, among the first thicknesses of the first insulating portion 60, a thickness t15 along the Z-axis direction is greater than the thickness (the first thickness t1) along the Y-axis direction.

In order for the first insulating portion 60 described above to be formed, the trench T5 is formed, and thereafter, As or P is ion-implanted into the semiconductor portion 30 exposed to the bottom portion of the trench T5. Therefore, in the bottom portion of the trench T5, the first insulating portion 60 is rapidly oxidized, and the thickness t15 along the Z-axis direction is made greater than the thickness (the first thickness t1) along the Y-axis direction.

In the structure described above, it is possible to reduce the gate capacitance and enhance the breakdown voltage on the bottom portion of the trench where the electric field is easily concentrated.

### Third Embodiment

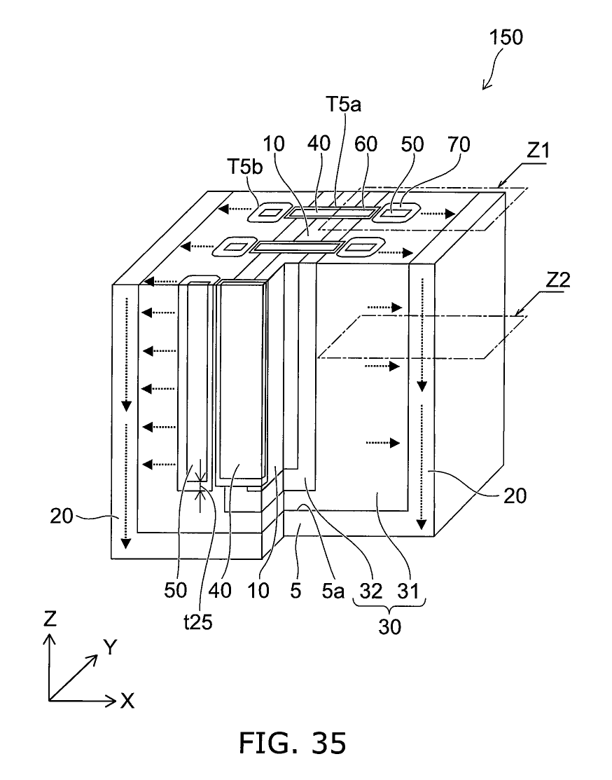

FIG. 35 is a schematic perspective view illustrating the configuration of a semiconductor device according to a third embodiment.

FIG. 35 shows a partially exploded schematic perspective view of a semiconductor device 150. Although FIG. 35 shows an example of the MOSFET, the same is true for the SBD.

As shown in FIG. 35, in the semiconductor device 150, the first insulating portion 60 is separated from the second insulating portion 70. That is, the first insulating portion 60 is separated from the second insulating portion 70 in the X-axis direction.

As described above, in the structure where the first insulating portion 60 is separated from the second insulating portion 70, when the semiconductor device 150 is manufactured, it is possible to form a trench T5a (a first electrode portion trench) for forming the first insulating portion 60 and the first electrode portion 40 and a trench T5b (a second electrode portion trench) for forming the second insulating portion 70 and the second electrode portion 50 in separate processes. That is, it is possible to form the trenches T5a and T5b under individually independent conditions. Therefore, it is possible to manufacture the trenches T5a and T5b that are individually designed as to a depth, a width and the like.

Furthermore, since the first insulating portion 60 formed within the trench T5a and the second insulating portion 70 formed within the trench T5b are independently formed, it is possible to accurately form the first insulating portion 60 and the second insulating portion 70 under individually desired conditions.

In the semiconductor device 150, the trench T5b is made deeper than the trench T5a, and thus it is possible to more increase the thickness t25 of the second insulating portion 70 in the Z-axis direction. For example, the thickness t25 is greater than the thickness t15 of the first insulating portion 60 shown in FIG. 24. As described above, in the structure where the thin first insulating portion 60 is surrounded by the thick second insulating portion 70, it is possible to improve the decrease in breakdown voltage on the bottom portion of the trench structure where the electric field is easily concentrated and to reduce the capacitance.

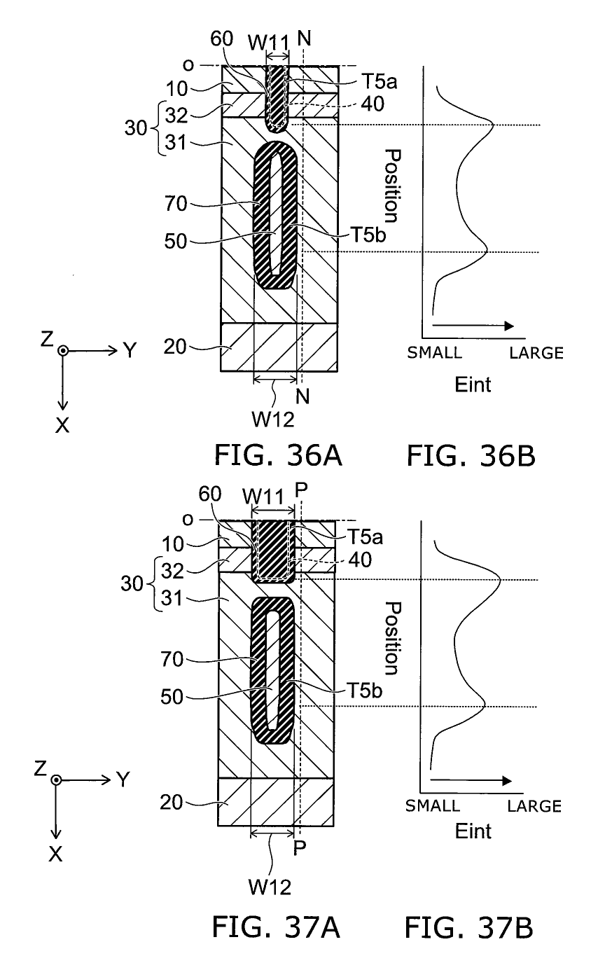

FIGS. 36A to 42B are diagrams illustrating variations of the structure within the trench.

In FIGS. 36A and 36B to 42A and 42B, FIGS. 36A, 37A, 38A, 39A, 40A 41A and 42A are schematic plan views of the Z1 portion shown in FIG. 35, and FIGS. 36B, 37B, 38B, 39B, 40B 41B and 42B illustrate an electric field strength distribution in a position along a line shown in FIGS. 36A, 37A, 38A, 39A, 40A 41A and 42A. In those figures, FIGS. 36A, 37A, 38A, 39A, 40A 41A and 42A show the first electrode portion 40 and the second electrode portion 50 on one side with the first conductive portion 10 in the center. Therefore, when a combination of the first electrode portion 40 and the second electrode portion 50 is line-symmetrically provided with respect to the first conductive portion 10, portions obtained by reversing the individual portions shown in FIGS. 36A, 37A, 38A, 39A, 40A 41A and 42A with respect to an alternate long and short dashed line o in the figures are formed. In the following description, for ease of description, only a combination of the first electrode portion 40 and the second electrode portion 50 on one side with the first conductive portion 10 in the center will be illustrated.

In the structure within the trench shown in FIG. 36A, as viewed in the Z-axis direction, the first insulating portion 60 formed within the trench T5a is separated from the second insulating portion 70 formed within the trench T5b in the X-axis direction. The width w12, as viewed in the Z-axis direction, of the trench T5b along the Y-axis is greater than the width w11, as viewed in the Z-axis direction, of the trench T5a along the Y-axis.

As shown in FIG. 36B, two crests of the electric field are provided on line N-N of the structure within the trench illustrated in FIG. 36A, and these two crests are balanced, with the result that the breakdown voltage can be enhanced.

Since the width w11 is narrower than the width w12, it is possible to reduce the electric field strength at an end portion of the first electrode portion 40 on the side of the second electrode portion 50, and to further enhance the breakdown voltage.

In the structure within the trench shown in FIG. 37A, as viewed in the Z-axis direction, the first insulating portion 60 formed within the trench T5a is separated from the second insulating portion 70 formed within the trench T5b in the X-axis direction. The width w12, as viewed in the Z-axis direction, of the trench T5b along the Y-axis is approximately equal to the width w11, as viewed in the Z-axis direction, of the trench T5a along the Y-axis.

As shown in FIG. 37B, two crests of the electric field are provided on line P-P of the structure within the trench illustrated in FIG. 37A, and these two crests are balanced, with the result that the breakdown voltage can be enhanced.

Although, in the structure within the trench shown in FIG. 37A, the opening of the trench T5a as viewed in the Z-axis direction penetrates the first conductive portion 10, the opening may be provided from midway through the first conductive portion 10 to midway through the first semiconductor region 31.

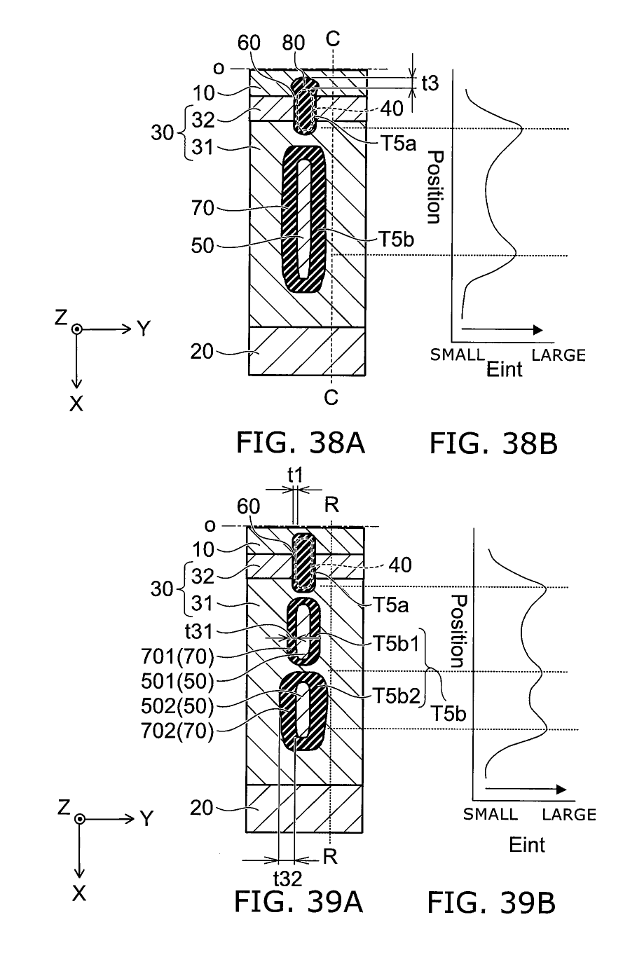

In the structure within the trench shown in FIG. 38A, the opening of the trench T5 as viewed in the Z-axis direction is provided along the X-axis direction from midway through the first conductive portion 10 to midway through the first semiconductor region 31. That is, the opening of the trench T5 as viewed in the Z-axis direction does not penetrate the first conductive portion 10. The first insulating portion 60 formed within the trench T5a is separated from the second insulating portion 70 formed within the trench T5b in the X-axis direction. The third insulting portion 80 is provided between the first electrode portion 40 and the first conductive portion 10. The third insulting portion 80 is formed integrally with the first insulating portion 60.

As shown in FIG. 38B, two crests of the electric field are provided on line Q-Q of the structure within the trench illustrated in FIG. 38A, and these two crests are balanced, with the result that the breakdown voltage can be enhanced.

The structure within the trench shown in FIG. 39A is a structure in which, as viewed in the Z-axis direction, the trench T5b is divided into a plurality of parts. In this example, the trench T5b is divided into two trenches, namely, a trench T5b1 and a trench T5b2. The two trenches, the trench T5b1 and the trench T5b2, are separated from each other in the X-axis direction.

Within the trench T5b1, a first portion 701 of the second insulating portion 70 and the sub-electrode portion 501 of the second electrode portion 50 are provided. Within the trench T5b2, a second portion 702 of the second insulating portion 70 and the sub-electrode portion 502 of the second electrode portion 50 are provided. The first portion 701 and the second portion 702 are separated from each other.

The thickness t31 of the first portion 701 is greater than the thickness t1 of the first insulating portion 60. The thickness t32 of the second portion 702 is greater than the thickness t31 of the first portion 701.

As shown in FIG. 39B, three crests of the electric field are provided on line R-R of the structure within the trench illustrated in FIG. 39A. Since the electric distribution can be shared by the three crests, it is possible to enhance the breakdown voltage. Even if the first impurity concentration in the first semiconductor region 31 is increased, it is possible to obtain sufficient breakdown voltage, with the result that the on resistance can be reduced. Although, in the example shown in FIG. 39A, the trench T5b is divided into two trenches, the trench T5b may be divided into a larger number of trenches.

Although, in the structure within the trench shown in FIG. 39A, the opening of the trench T5a as viewed in the Z-axis direction is provided from midway through the first conductive portion 10 to midway through the first semiconductor region 31, the opening may be provided to penetrate the first conductive portion 10.

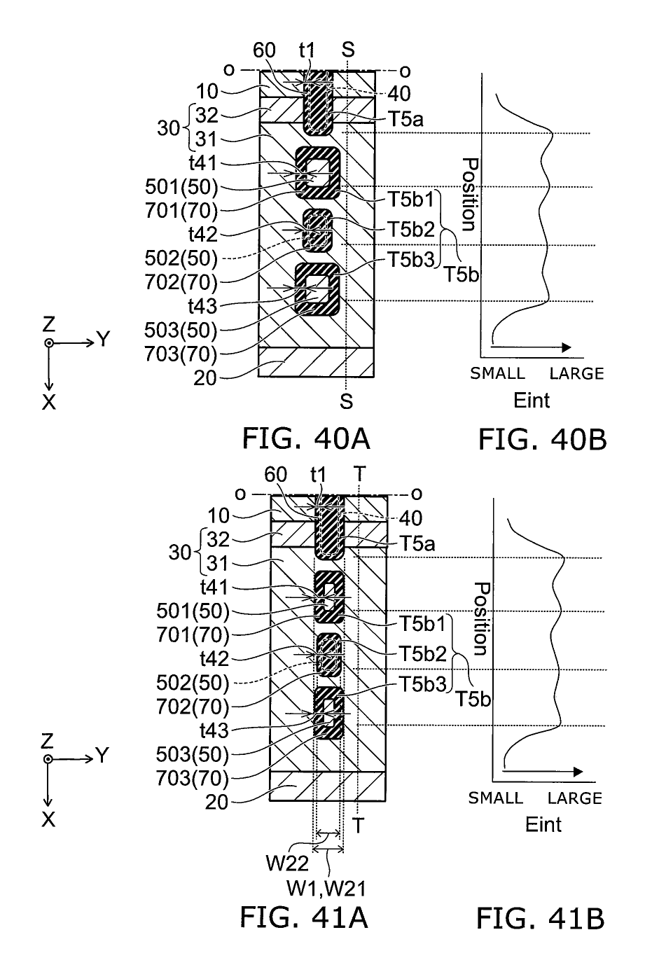

In the structure within the trench shown in FIG. 40A, the trench T5b is divided into three trenches, namely, the trenches T5b1, T5b2 and T5b3. Within the trench T5b1, the first portion 701 of the second insulating portion 70 and the sub-electrode portion 501 of the second electrode portion 50 are provided. Within the trench T5b2, the second portion 702 of the second insulating portion 70 and the sub-electrode portion 502 of the second electrode portion 50 are provided. Within the trench T5b3, a third portion 703 of the second insulating portion 70 and the sub-electrode portion 503 of the second electrode portion 50 are provided.

The first portion 701, the second portion 702 and the third portion 703 are separated from each other.

The thickness t41 of the first portion 701 is greater than the thickness t1 of the first insulating portion 60. The thickness t42 of the second portion 702 is smaller than the thickness t41 of the first portion 701. The thickness t43 is greater than the thickness t42 of the second portion 702. That is, the thickness of the second insulating portion 70 alternately becomes thick and small along the X-axis.

As shown in FIG. 40B, four crests of the electric field are provided on line S-S of the structure within the trench illustrated in FIG. 40A. Since the electric distribution can be shared by the four crests, it is possible to enhance the breakdown voltage. Even if the first impurity concentration in the first semiconductor region 31 is increased, it is possible to obtain sufficient breakdown voltage, with the result that the on resistance can be reduced.

In the structure within the trench shown in FIG. 41A, as with the trench shown in FIG. 40A, the trench T5b is divided into the three trenches T5b1, T5b2 and T5b3. In the structure illustrated in FIG. 41A, the width w21 of the trenches T5b1 and T5b3 along the Y-axis direction is approximately equal to the width w11 of the trench T5a along the Y-axis direction.

The width w22 of the trench T5b2 along the Y-axis direction is narrower than the width w11 of the trench T5a.

As with the structure within the trench shown in FIGS. 39A and 39B, the thickness t41 of the first portion 701, the thickness t42 of the second portion 702 and the thickness t43 of the third portion 703 alternately become thick and small along the X-axis.

As shown in FIG. 41B, four crests of the electric field are provided on line T-T of the structure within the trench illustrated in FIG. 41A. Since the electric distribution can be shared by the four crests, it is possible to enhance the breakdown voltage. Even if the first impurity concentration in the first semiconductor region 31 is increased, it is possible to obtain sufficient breakdown voltage, with the result that the on resistance can be reduced.

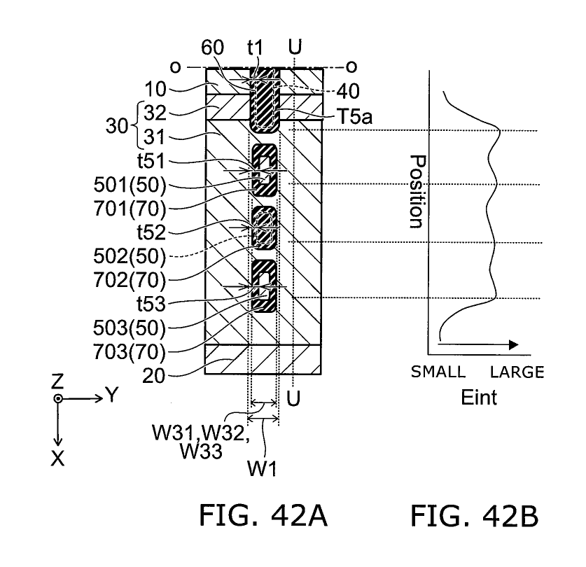

In the structure within the trench shown in FIG. 42A, as with the trench shown in FIG. 41A, the trench T5b is divided into the three trenches T5b1, T5b2 and T5b3. In the structure illustrated in FIG. 42A, the widths w31, w32 and w33 of the trenches T5b1, T5b2 and T5b3 along the Y-axis direction are approximately equal to each other, and are narrower than the width w11 of the trench T5a along the Y-axis direction.

As with the structure within the trench shown in FIGS. 39A and 39B, the thickness t51 of the first portion 701, the thickness t52 of the second portion 702 and the thickness t53 of the third portion 703 alternately become thick and small along the X-axis.

As shown in FIG. 42B, four crests of the electric field are provided on line U-U of the structure within the trench illustrated in FIG. 42A. Since the electric distribution can be shared by the four crests, it is possible to enhance the breakdown voltage. Even if the first impurity concentration in the first semiconductor region 31 is increased, it is possible to obtain sufficient breakdown voltage, with the result that the on resistance can be reduced.

In the structures within the trenches shown in FIGS. 39A and 39B to 42A and 42B, when the trench T5a and the trench T5b (the trenches T5b1, T5b2 and T5b3) are formed, the depth of the trench can be set by the width of the opening as viewed in the Z-axis direction. That is, isotropic ion etching is performed in the formation of the trench, and thus it is possible to set the depth of the trench corresponding to the width of the opening of the trench.

The trenches (the trenches T5b1, T5b2 and T5b3) are individually formed, and thus it is possible to set each depth regardless of the width of the opening of the trench. In this way, the flexibility of the design of the trench is enhanced.

Although, in the structure within the trench shown in FIGS. 40A and 40B to 42A and 42B, the opening of the trench T5a as viewed in the Z-axis direction penetrates the first conductive portion 10, the opening may be provided from midway through the first conductive portion 10 to midway through the first semiconductor region 31.

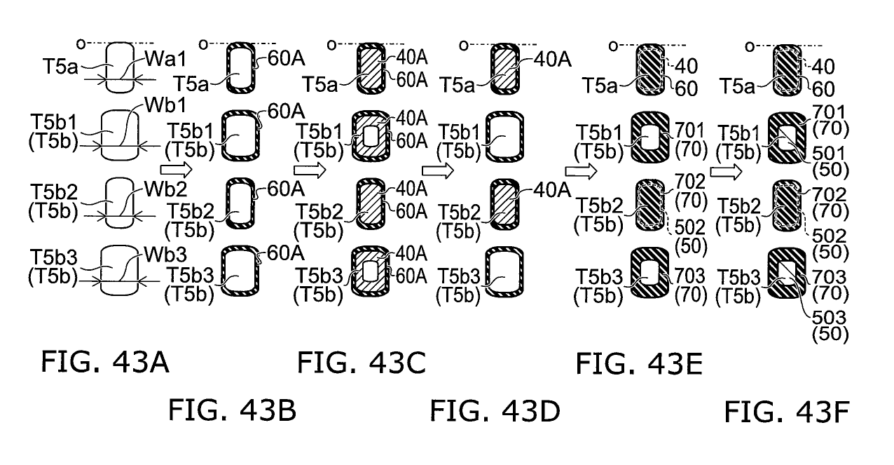

FIGS. 43A to 43F are schematic views illustrating the method (a first method) of manufacturing the structure within the trench having divided trenches.

FIGS. 43A to 43F show schematic plan views of the Z1 portion shown in FIG. 35 in order of the processes. For ease of description, only the state of the interior of the trenches T5a and T5b (T5b1 to T5b3) will be illustrated.

The manufacturing method shown in FIGS. 43A to 43F is an example of the method of manufacturing the structure within the trench shown in FIG. 40A.

First, as shown in FIG. 43A, the trenches T5a and T5b (T5b1 to T5b3) are formed. Each of the trenches T5a and T5b (T5b1 to T5b3) has an independent opening. The widths wa1, wb1, wb2 and wb3 along the Y-axis direction of the openings as viewed in the Z-axis direction of the trenches T5a and T5b (T5b1 to T5b3) are set in response to the final forms shown in FIGS. 40A, 41A and 42A.

The trenches T5a and T5b (T5b1 to T5b3) may be formed in individually different processes or may be formed in the same process. When the trenches T5a and T5b (T5b1 to T5b3) are formed in individually different processes, the widths and depths of the trenches can be independently set. When the trenches T5a and T5b (T5b1 to T5b3) are formed in the same process, the depth of etching can be set depending on the width of the trench.

Then, as shown in FIG. 43B, the insulating film 60A is formed on the inside wall of the trenches T5a and T5b (T5b1 to T5b3). The insulating film 60A is, for example, a thermal oxide film of silicon. Then, as shown in FIG. 43C, the first electrode film 40A is formed on the insulating film 60A within the trenches T5a and T5b (T5b1 to T5b3). The first electrode film 40A is, for example, a polysilicon containing an impurity. The first electrode film 40A is deposited on the insulating film 60A.

The first electrode film 40A is embedded in the trenches of a narrow width (for example, the trenches T5a and T5b2), and is formed in the trenches of a great width (for example, the trenches T5b1 and T5b3) such that a space is left.

Next, as shown in FIG. 43D, the first electrode film 40A provided in the trenches T5b1 and T5b3 is removed. Then, as shown in FIG. 43E, a portion of the first electrode film 40A is oxidized. That is, when, for example, a polysilicon is used as the first electrode film 40A, oxidation processing is performed under an atmosphere of oxygen, and the portion is changed into a silicon oxide film. The oxidation of the first electrode film 40A progresses from a portion exposed to the spaces of the trenches T5b1 and T5b3 and the upper face (exposed portion) of the trenches T5a and T5b3. In the trenches T5b1 and T5b3, the thickness of the insulating film 60A is increased.

By the oxidation described above, the first electrode film 40A in the trenches T5b1 to T5b3 serves as the first portion 701, the second portion 702 and the third portion 703 of the second insulating portion 70. In contrast, although the trench T5a is oxidized from the upper face (the exposed portion) to a portion of the interior, a portion that is left without being oxidized serves as the first electrode portion 40.

The insulating film 60A present between the first electrode portion 40 and the inside wall of the trench T5a serves as the first insulating portion 60. In contrast, although the trench T5b2 is oxidized from the upper face (the exposed portion) to a portion of the interior, a portion that is left without being oxidized serves as the sub-electrode portion 502 of the second electrode portion 50.

Next, as shown in FIG. 43F, the sub-electrode portions 501 and 503 of the second electrode portion 50 are formed in the spaces surrounded by the second insulating portion 70 within the trenches T5b1 and T5b3. For example, a polysilicon is used as the sub-electrode portions 501 and 503. By the processes described above, the structure within the trench is completed.

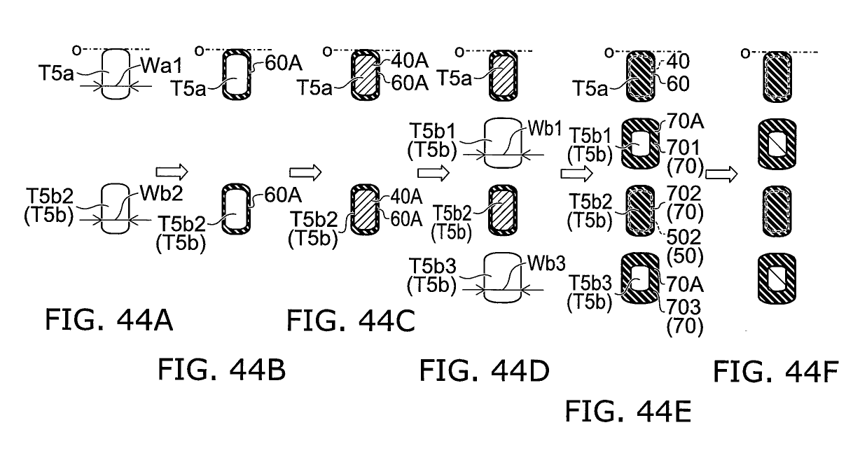

FIGS. 44A to 44F are schematic views illustrating the method (a second method) of manufacturing the structure within the trench having divided trenches.

FIGS. 44A to 44F show schematic plan views of the Z1 portion shown in FIG. 35 in order of the processes. For ease of description, only the state of the interior of the trenches T5a and T5b (T5b1 to T5b3) will be illustrated.

The manufacturing method shown in FIGS. 44A to 44F is an example of the method of manufacturing the structure within the trench shown in FIG. 40A.

First, as shown in FIG. 44A, the trenches T5a and T5b2 are formed. The widths wa1 and wb2 along the Y-axis direction of the opening as viewed in the Z-axis direction of the trenches T5a and T5b2 are substantially the same. Therefore, these trenches T5a and T5b2 are formed in the same process, and thus it is possible to form the trenches T5a and T5b2 of the same depth in the same process.

Next, as shown in FIG. 44B, the insulating film 60A is formed on the inside wall of the trenches T5a and T5b2. The insulating film 60A is, for example, a thermal oxide film of silicon. Then, as shown in FIG. 44C, the first electrode film 40A is embedded in the trenches T5a and T5b2. The first electrode film 40A is, for example, a polysilicon containing an impurity. The first electrode film 40A is deposited on the insulating film 60A.

Then, as shown in FIG. 44D, the trenches T5b1 and T5b3 are formed. The widths wb1 and wb3 along the Y-axis direction of the opening as viewed in the Z-axis direction of the trenches T5b1 and T5b3 are substantially the same. Therefore, these trenches T5b1 and T5b3 are formed in the same process, and thus it is possible to form the trenches T5b1 and T5b3 of the same depth in the same process. When the trenches T5b1 and T5b3 are formed, the trenches T5a and T5b2 are masked.

Next, as shown in FIG. 44E, the insulating film 70A is formed on the inside wall of the trenches T5b1 and T5b3. The insulating film 70A is, for example, a thermal oxide film on which oxidation processing has been performed under an atmosphere of oxygen.

By the oxidation described above, the insulating film 70A formed in the trenches T5b1 and T5b3 serves as the first portion 701 and the third portion 703 of the second insulating portion 70. Although the trench T5b2 is oxidized from the upper face (the exposed portion) up to a portion of the interior, a portion that is left without being oxidized serves as the sub-electrode portion 502 of the second electrode portion 50. The insulating film 60A present between the inside wall of the trench T5b2 and the sub-electrode portion 502 serves as the second portion 702 of the second insulating portion 70.

In contrast, although the trench T5a is oxidized from the upper face (the exposed portion) up to a portion of the interior, a portion that is left without being oxidized serves as the first electrode portion 40. The insulating film 60A present between the first electrode portion 40 and the inside wall of the trench T5a serves as the first insulating portion 60.

Then, as shown in FIG. 44F, the sub-electrode portions 501 and 503 of the second electrode portion 50 are formed in the spaces surrounded by the second insulating portion 70 within the trenches T5b1 and T5b3. For example, a polysilicon is used as the sub-electrode portions 501 and 503. By the processes described above, the structure within the trench is completed.

The manufacturing method illustrated in FIGS. 43A to 43F and 44A to 44F can be likewise applied even to the structure within the trench shown in FIGS. 41A and 42A.

### Fourth Embodiment

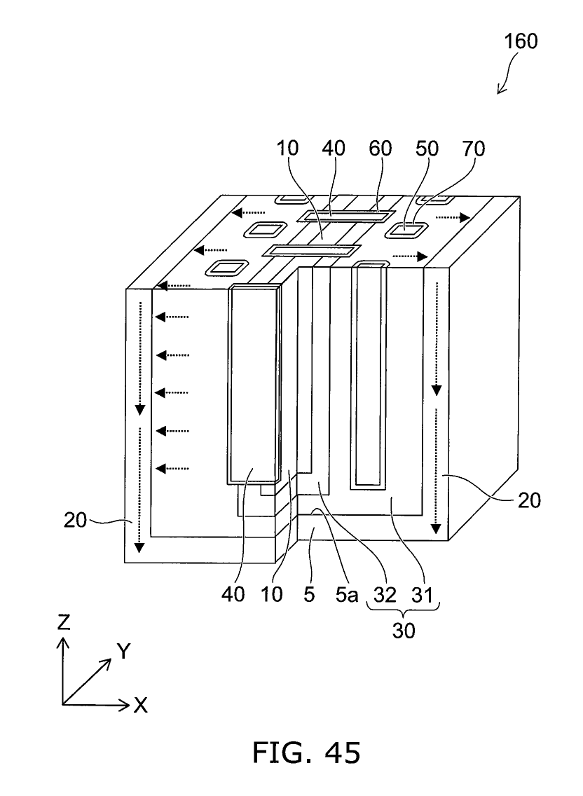

FIG. 45 is a schematic perspective view illustrating the configuration of a semiconductor device according to a fourth embodiment.

FIG. 45 shows a partially exploded schematic perspective view of a semiconductor device 160.

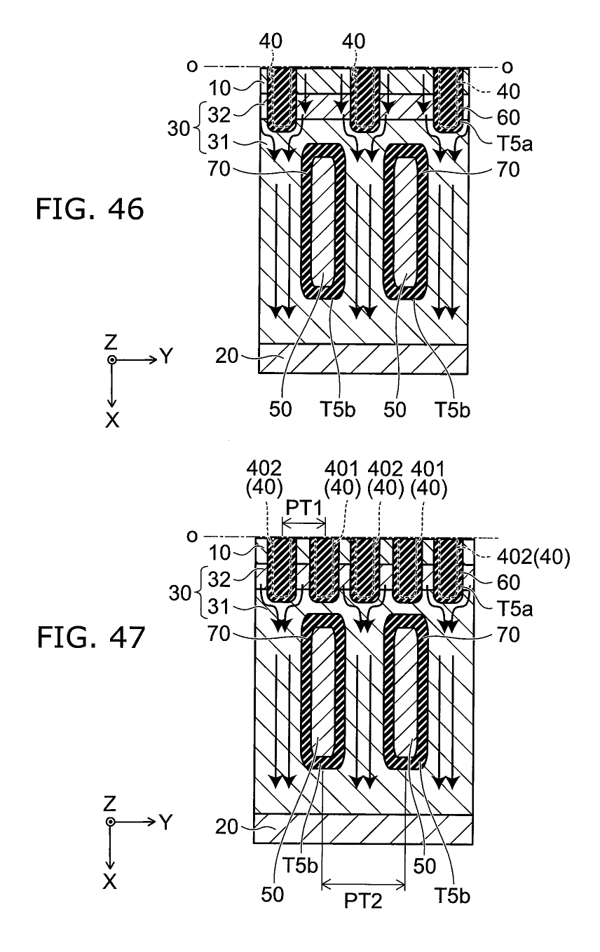

FIG. 46 is a schematic plan view illustrating the configuration of the semiconductor device according to the fourth embodiment.

FIG. 46 shows part of a flat face of the semiconductor device 160 illustrated in FIG. 45.

Although FIGS. 45 and 46 show an example of the MOSFET, the same is true for the SBD.

As shown in FIG. 45, in the semiconductor device 160, the first insulating portion 60 is separated from the second insulating portion 70. That is, the first insulating portion 60 is separated from the second insulating portion 70 in the X-axis direction. Furthermore, the first electrode portion 40 and the second electrode portion 50 are displaced along the Y-axis direction. The position of the second electrode portion 50 along the Y-axis direction is located between the adjacent two first electrode portions 40 in the Y-axis direction. That is, a plurality of first electrode portions 40 and a plurality of second electrode portions 50 are displaced, by a half pitch, from each other along the Y-axis direction.

Arrows shown in FIG. 46 represent the direction of flow of electrons. In the semiconductor device 160, when a voltage beyond a threshold value is applied to the first electrode portion 40, a channel is formed in the second semiconductor region 32, and a current flows toward the second conductive portion 20 opposite the first conductive portion 10.

In this case, since the second electrode portion 50 and the second insulating portion 70 are not disposed between the first electrode portion 40 and the second conductive portion 20, electrons traveling around toward the side of an end portion of the first electrode portion 40 flow to the second conductive portion 20 without being interrupted by the second electrode portion 50 and the second insulating portion 70. Thus, it is possible to reduce the on resistance.

FIGS. 47 to 49 are schematic plan views illustrating other structures of the semiconductor device according to the fourth embodiment.

FIGS. 47 to 49 show the part of the flat face of the semiconductor device 160 illustrated in FIG. 45.

Although FIGS. 47 to 49 show an example of the MOSFET, the same is true for the SBD.

In the structure shown in FIG. 47, the pitch PT1 of the first electrode portions 400 along the Y-axis direction is narrower than the pitch PT2 of the second electrode portions 50 along the Y-axis direction. For example, first electrode portions 401 are provided opposite the second electrode portions 50. A first electrode portion 402 is provided between a plurality of first electrode portions 401. For example, the pitch PT1 is half the pitch PT2.

As described above, since, within the same range along the Y-axis direction, the number of first electrode portions 40 is more than that of the second electrode portions 50, as compared with a case where the number of first electrode portions 40 is equal to that of the second electrode portions 50, it is possible to reduce resistance of the channel and thus reduce the on resistance.

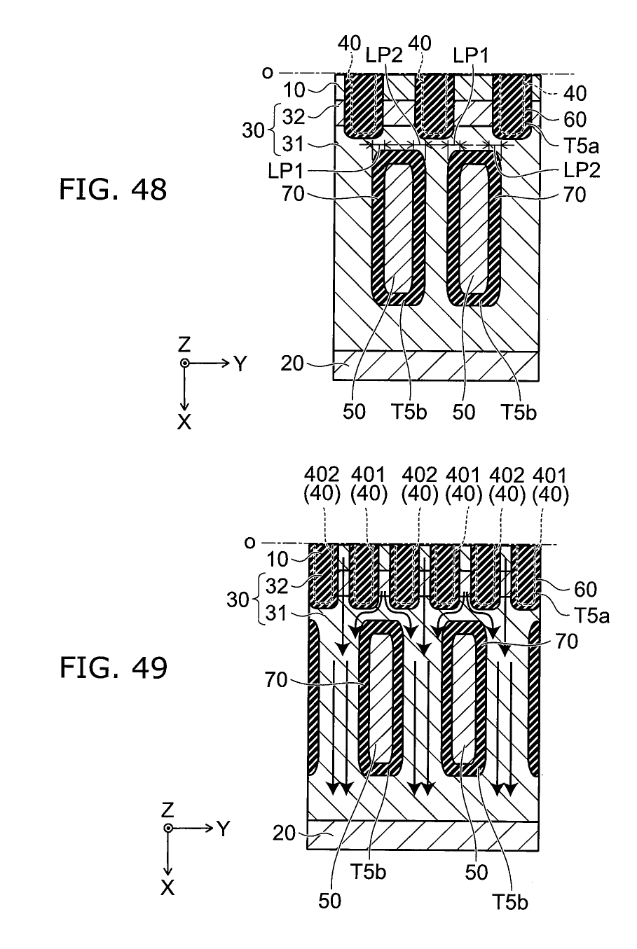

In the structure shown in FIG. 48, as viewed in the X-axis direction, a part of the trench T5a overlaps with a part of the trench T5b. The trench T5b disposed between adjacent two trenches T5a as viewed in the Y-axis direction has a part overlapping the two trenches T5a. Thus, as viewed in the X-axis direction, a part of the first insulating portion 40 overlaps with a part of the second insulating portion 70. The width along the Y-axis direction of a part where one of the two trenches T5a overlaps with the trench T5b as viewed in the X-axis direction is LP1. The width along the Y-axis direction of a part in which the other of the two trenches T5a overlaps with the trench T5b as viewed in the X-axis direction is LP2. For example, the width LP1 is equal to the width LP2. The width LP1 may be either greater than or shorter than the width LP2.

In the structure described above, the electric field at an end portion of the first electrode portion 40 on the side of the second electrode portion 50 is alleviated, and thus it is possible to enhance the breakdown voltage.

In the structure shown in FIG. 49, a part between adjacent two trenches T5a overlaps with a part between adjacent two trenches T5b as viewed in the X-axis direction. In the example shown in FIG. 49, each alternate part between adjacent two trenches T5a overlaps with the part between adjacent two trenches T5b as viewed in the X-axis direction. When the part between adjacent two trenches T5a overlaps with the part between adjacent two trenches T5b as viewed in the X-axis direction, a current flows smoothly from the first conductive portion 10 to the second conductive portion 20. Thus, it is possible to reduce the on resistance.

In the semiconductor device 160 shown in FIGS. 45 to 49, the aspects shown in FIGS. 45 to 49 or various aspects described previously may be applied to the structure of the trench T5a for the first electrode portion 40 and the first insulating portion 60 and the structure of the trench T5b for forming the second electrode portion 50 and the second insulating portion 70.

As described above, according to the semiconductor device and its manufacturing method according to the embodiment, it is possible to provide a semiconductor device that can enhance the breakdown voltage.

Although the embodiment and the variations thereof have been described above, the invention is not limited to these examples. For example, examples that are obtained through the addition, the deletion and the design change of constituent elements by a person skilled in the art as appropriate and examples that are obtained by combing features of the embodiments as appropriate are included in the scope of the invention as long as they includes the spirit of the invention.

For example, although, in the description of the embodiments and the variations discussed above, the first conductive form is the n-type, and the second conductive form is the p-type, the invention can be practiced even when the first conductive form is the p-type, and the second conductive form is the n-type.

In the semiconductor devices 120, 121, 122, 123, 130, 140, 150 and 160, the electric field alleviation region 33 as in the semiconductor device 110 may be provided. Thus, it is possible to alleviate the concentration of the electric filed of the first insulating portion 60 and the second insulating portion 70 on the side of the substrate 5 and to enhance the breakdown voltage.

The electric field alleviation region 33 is not limited to the one shown in FIG. 1.

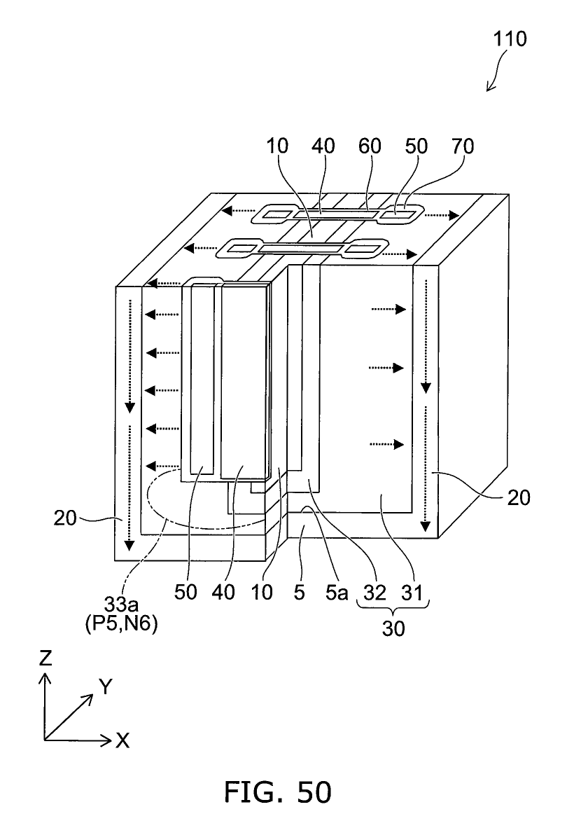

FIG. 50 is a schematic perspective view illustrating another electric field alleviation region.

As shown in FIG. 50, the electric field alleviation region 33a may not be formed to be larger than the one illustrated in FIG. 1. The electric field alleviation region 33a shown in FIG. 50 is the semiconductor portion 30, and is formed so as to cover the end portion of the second semiconductor region 32 from the side of the first insulating portion 60 and the second insulating portion 70. Thus, it is possible to further enhance the breakdown voltage at the end portion of the second semiconductor region 32.

The electric field alleviation region 33a may be applied to the MOSFET structures according to the other embodiments.

Furthermore, in the embodiments and the variations described above, the MOSFET and the SBD using Si (silicon) as the semiconductor have been described, as the semiconductor, a compound semiconductor such as SiC (silicon carbide) or GaN (gallium nitride) or a wideband gap semiconductor such as diamond can be used.

Although several embodiments of the invention have been described, these embodiments are illustrative, and are not intended to limit the scope of the invention. These novel embodiments can be practiced in various other forms; various deletions, replacements and modifications are possible without departing from the spirit of the invention. These embodiments and the variations thereof are included in the scope and the spirit of the invention, and are included in a scope equivalent to the invention described in the scope of claims.

The embodiment includes the following aspects.

(Addition 1)

A semiconductor device comprising:

a substrate;

a first conductive portion extending in a first direction perpendicular to a major surface of the substrate;

a second conductive portion extending in the first direction and provided to be separated from the first conductive portion along a second direction perpendicular to the first direction;

a semiconductor portion provided between the first conductive portion and the second conductive portion and including a first semiconductor region of a first impurity concentration and of a first conductive form;

a first electrode portion extending in the first direction between the first conductive portion and the second conductive portion;

a second electrode portion extending in the first direction between the first conductive portion and the second conductive portion and provided to be separated from the first electrode portion;

a first insulting portion provided between the first electrode portion and the semiconductor portion and having a first thickness in a normal direction of a boundary face of the first electrode portion; and

a second insulating portion provided between the second electrode portion and the semiconductor portion and having a second thickness greater than the first thickness in a normal direction of a boundary face of the second electrode portion.

(Addition 2)

The device according to addition 1, wherein the first electrode portion is provided along the second direction from midway through the first conductive portion to midway through the semiconductor portion.

(Addition 3)

The device according to addition 1 or 2, wherein the second thickness is gradually increased from the first conductive portion to the second conductive portion.

(Addition 4)

The device according to addition 1 or 2, wherein the second thickness is repeatedly increased and decreased from the first conductive portion to the second conductive portion.

(Addition 5)

The device according to any one of additions 1 to 4, wherein the second electrode portion includes a plurality of electrode regions disposed to be separated from each other in the second direction.

(Addition 6)

The device according to addition 5, wherein the first insulting portion and the second insulating portion are provided to be separated in the second direction, and the second electrode portions are provided to be separated for each of the plurality of electrode regions.

(Addition 7)

The device according to any one of additions 1 to 6, wherein, among the first thicknesses, a thickness along the first direction is greater than a thickness along the second direction.

(Addition 8)

The device according to any one of additions 1 to 7, further comprising:

a third insulating portion provided between the first electrode portion and the first conductive portion and having a third thickness greater than the first thickness in a direction in which the boundary face of the first electrode portion is opposite a boundary face of the first conductive portion.

(Addition 9)

The device according to any one of additions 1 to 8, wherein the semiconductor portion includes a second semiconductor region of a second conductive form provided between the first conductive portion and the first semiconductor region, and

the first electrode portion and the first insulating portion penetrate the second conductor region along the second direction.

(Addition 10)

The device according to addition 9, wherein a length of the second electrode portion along the first direction is greater than a length of the first electrode portion along the first direction.

(Addition 11)

The device according to any one of additions 1 to 8, wherein the first electrode portion is in electrical conduction with the first conductive portion, and

the first conductive portion is Schottky-junctioned to the semiconductor portion.

(Addition 12)

The device according to addition 11, wherein the semiconductor portion includes, on a side of the first conductive portion of the semiconductor portion, a first concentration region of the first conductive form and of an impurity concentration lower than the first impurity concentration.

(Addition 13)

The device according to addition 11, wherein the semiconductor portion includes, on a side of the first conductive portion of the semiconductor portion, a second concentration region of the first conductive form and of an impurity concentration higher than the first impurity concentration.

(Addition 14)

The device according to any one of additions 11 to 13, wherein the semiconductor portion includes a third concentration region of a second conductive form between the substrate and the first conductive portion on a side of the first conductive portion.

(Addition 15)

The device according to any one of additions 11 to 13, wherein the semiconductor portion includes a fourth concentration region of the first conductive form and of an impurity concentration lower than the first impurity concentration between the substrate and the first conductive portion on a side of the first conductive portion.

(Addition 16)

The device according to any one of additions 11 to 14, wherein the first electrode portion is provided to be separated from a boundary face between the first conductive portion and the semiconductor portion.

(Addition 17)

The device according to any one of additions 1 to 16, wherein the first insulting portion and the second insulating portion are provided to be separate in the second direction.

(Addition 18)

The device according to addition 17, wherein the first insulating portion is provided to be separated from the second insulating portion, and

a position of the first insulting portion along a third direction perpendicular to the first direction and the second direction is different from a position of the second insulting portion along the third direction.

(Addition 19)

The device according to addition 18, wherein, as viewed in the second direction, a part of the first insulating portion overlaps with a part of the second insulting portion.

(Addition 20)

The device according to addition 17, wherein a plurality of the first electrode portions are provided in the third direction at a first pitch, and

a plurality of the second electrode portions are provided in the third direction at a second pitch greater than the first pitch.

(Addition 21)

The device according to any one of additions 1 to 20, wherein a length of the second insulating portion along the first direction is greater than a length of the first insulating portion along the first direction.

(Addition 22)

The device according to any one of additions 1 to 21, wherein the semiconductor portion includes a fifth concentration region of the second conductive form between the substrate and the first conductive portion on a side of at least the first insulating portion and the second insulating portion.

(Addition 23)

The device according to any one of additions 1 to 21, wherein the semiconductor portion includes a sixth concentration region of the first conductive form and of an impurity concentration lower than the first impurity concentration between the substrate and the first conductive portion on a side of at least the first insulating portion and the second insulating portion.

(Addition 24)

A method of manufacturing a semiconductor device including: a substrate; a first conductive portion extending in a first direction perpendicular to a major surface of the substrate; a second conductive portion extending in the first direction and provided to be separated from the first conductive portion along a second direction perpendicular to the first direction; a semiconductor portion provided between the first conductive portion and the second conductive portion and including a first semiconductor region of a first impurity concentration and of a first conductive form; a first electrode portion extending in the first direction between the first conductive portion and the second conductive portion; a second electrode portion extending in the first direction between the first conductive portion and the second conductive portion and provided to be separated from the first electrode portion; a first insulting portion provided between the first electrode portion and the semiconductor portion and having a first thickness in a normal direction of a boundary face of the first electrode portion; and a second insulating portion provided between the second electrode portion and the semiconductor portion and having a second thickness greater than the first thickness in a normal direction of a boundary face of the second electrode portion, the method of manufacturing a semiconductor device including, when the first electrode portion and the second electrode portion are formed,:

a process of forming a first trench obtained by removing a part of the semiconductor portion in the first direction and having a first opening width in a third direction perpendicular to the first direction and the second direction and a second opening width greater than the first opening width in the third direction;

a process of forming a first insulating film on an inside wall of the first trench;

a process of forming a first electrode film on a film face of the first insulting film, embedding the first electrode film in a portion of the first opening width and forming a space where the first electrode film is not embedded in a portion of the second opening width;

a process of oxidizing a part of the first electrode film to form the second insulating portion and the first insulting portion and the first electrode portion; and

a process of forming a second electrode film within the space to form the second electrode portion.

(Addition 25)

The method according to addition 24, wherein the process of forming the space includes a process of selectively removing the first electrode film formed in the second opening width to enlarge the space.

(Addition 26)

The method according to addition 24 or 25, wherein the process of oxidizing the part of the first electrode film includes a process of oxidizing the first insulating film between the first electrode portion and the first conductive portion at an oxidation speed faster than a speed of oxidizing the first electrode film in a portion of the second opening width so as to form a third insulating portion having a third thickness greater than the first thickness.

(Addition 27)

The method according to any one of additions 24 to 26, wherein the semiconductor portion includes a second semiconductor region of a second conductive form provided between the first conductive portion and the first semiconductor region, and

the process of forming the first insulating portion and the first electrode portion includes a process of forming the first insulating portion and the first electrode portion such that the first insulating portion and the first electrode portion penetrate the second semiconductor region along the second direction.

(Addition 28)

The method according to any one of additions 24 to 26, the method further including:

a process of forming the first electrode portion, and then removing the part of the first electrode portion and the part of the semiconductor portion in the first direction so as to form a second trench; and

a process of embedding a first conductive film within the second trench so as to make the first conductive portion in electrical conduction with the first electrode portion and to make the first conductive portion Schottky-junctioned to the semiconductor portion.

(Addition 29)

The method according to addition 28, wherein the process of forming the second trench includes a process of implanting an impurity into the semiconductor portion exposed from an inside wall of the second trench to include a first concentration region of the first conductive form and having an impurity concentration lower than the first impurity concentration.

(Addition 30)

The method according to addition 28, wherein the process of forming the second trench includes a process of implanting an impurity into the semiconductor portion exposed from an inside wall of the second trench to include a second concentration region of the first conductive form and of an impurity concentration higher than the first impurity concentration.

(Addition 31)

The method according to addition 28, wherein the process of forming the second trench includes a process of implanting an impurity into a bottom portion of the second trench to form a third concentration region of a second conductive form between the substrate and the semiconductor portion on a side of the first conductive portion.

(Addition 32)

The method according to addition 28, wherein the process of forming the second trench includes a process of implanting an impurity into a bottom portion of the second trench to form a fourth concentration region of a first conductive form and of an impurity concentration lower than the first impurity concentration between the substrate and the semiconductor portion on a side of the first conductive portion.

(Addition 33)

The method according to any one of additions 24 to 32, wherein the first trench includes a first electrode trench in a portion of the first opening width and a second electrode trench in a portion of the second opening width,

the first electrode trench and the second electrode trench are formed to be separate,

the first insulating portion and the first electrode portion are formed within the first electrode trench and

the second insulating portion and the second electrode portion are formed within the second electrode trench.

(Addition 34)

The method according to addition 33, wherein the first insulating portion within the first electrode trench and the second insulating portion within the second electrode trench are formed in different processes.

(Addition 35)

The method according to addition 33, wherein the first insulating portion within the first electrode trench and the second insulating portion within the second electrode trench are formed in the same process.

(Addition 36)

The method according to any one of additions 33 to 35, wherein the first electrode trench along the third direction and the second electrode trench along the third direction are formed such that positions thereof are displaced from each other.

(Addition 37)

A method of manufacturing a semiconductor device including: a substrate; a first conductive portion extending in a first direction perpendicular to a major surface of the substrate; a second conductive portion extending in the first direction and provided to be separated from the first conductive portion along a second direction perpendicular to the first direction; a semiconductor portion provided between the first conductive portion and the second conductive portion and including a first semiconductor region of a first impurity concentration and of a first conductive form; a first electrode portion extending in the first direction between the first conductive portion and the second conductive portion; a second electrode portion extending in the first direction between the first conductive portion and the second conductive portion and provided to be separated from the first electrode portion; a first insulting portion provided between the first electrode portion and the semiconductor portion and having a first thickness in a normal direction of a boundary face of the first electrode portion; and a second insulating portion provided between the second electrode portion and the semiconductor portion and having a second thickness greater than the first thickness in a normal direction of a boundary face of the second electrode portion, the method of manufacturing a semiconductor device including, when the first electrode portion and the second electrode portion are formed,:

a process of removing a part of the semiconductor portion in the first direction to form a third trench;

a process of forming a second insulating film on an inside wall of the third trench to form a second electrode film through the second insulating film;

a process removing the first insulating film and the second electrode film provided in a first portion which is a part on an opposite side to the second conductive portion within the third trench so as to form the second insulating portion and the second electrode portion;

a process of forming a first insulating portion on an inside wall of the third trench in the first portion; and

a process of forming the first electrode portion in the first portion through the first insulating portion.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a substrate;
a first conductive portion extending in a first direction perpendicular to a major surface of the substrate;
a second conductive portion extending in the first direction and provided to be separated from the first conductive portion along a second direction perpendicular to the first direction;
a semiconductor portion provided between the first conductive portion and the second conductive portion and including a first semiconductor region of a first impurity concentration and of a first conductive form;
a first electrode portion extending in the first direction between the first conductive portion and the second conductive portion;
a second electrode portion extending in the first direction between the first conductive portion and the second conductive portion and provided to be separated from the first electrode portion;
a first insulting portion provided between the first electrode portion and the semiconductor portion and having a first thickness in a normal direction of a boundary face of the first electrode portion; and
a second insulating portion provided between the second electrode portion and the semiconductor portion and having a second thickness greater than the first thickness in a normal direction of a boundary face of the second electrode portion.

2. The device according to claim 1, wherein the first electrode portion is provided along the second direction from midway through the first conductive portion to midway through the semiconductor portion.

3. The device according to claim 1, wherein the second thickness is gradually increased from the first conductive portion to the second conductive portion.

4. The device according to claim 1, wherein the second thickness is repeatedly increased and decreased from the first conductive portion to the second conductive portion.

5. The device according to claim 1, wherein the second electrode portion includes a plurality of electrode regions disposed to be separated from each other in the second direction.

6. The device according to claim 5, wherein the first insulting portion and the second insulating portion are provided to be separated from each other in the second direction, and the second electrode portions are provided to be separated from each other for each of the plurality of electrode regions.

7. The device according to claim 1, wherein, among the first thicknesses, a thickness along the first direction is greater than a thickness along the second direction.

8. The device according to claim 1, further comprising:
a third insulating portion provided between the first electrode portion and the first conductive portion and having a third thickness greater than the first thickness in a direction in which the boundary face of the first electrode portion and a boundary face of the first conductive portion face each other.

9. The device according to claim 1, wherein
the semiconductor portion includes a second semiconductor region of a second conductive form provided between the first conductive portion and the first semiconductor region, and
the first electrode portion and the first insulating portion penetrate the second conductor region along the second direction.

10. The device according to claim 9, wherein a length of the second electrode portion along the first direction is greater than a length of the first electrode portion along the first direction.

11. The device according to claim 1, wherein
the first electrode portion is in electrical conduction with the first conductive portion, and
the first conductive portion is Schottky-junctioned to the semiconductor portion.

12. The device according to claim 11, wherein the semiconductor portion includes, on a side of the first conductive portion of the semiconductor portion, a first concentration region of the first conductive form and of an impurity concentration lower than the first impurity concentration.

13. The device according to claim 11, wherein the semiconductor portion includes, on a side of the first conductive portion of the semiconductor portion, a second concentration region of the first conductive form and of an impurity concentration higher than the first impurity concentration.

14. The device according to claim 11, wherein the semiconductor portion includes a third concentration region of a second conductive form between the substrate and the first conductive portion on a side of the first conductive portion.

15. The device according to claim 11, wherein the semiconductor portion includes a fourth concentration region of the first conductive form and of an impurity concentration lower than the first impurity concentration between the substrate and the first conductive portion on a side of the first conductive portion.

16. The device according to claim 11, wherein the first electrode portion is provided to be separated from a boundary face between the first conductive portion and the semiconductor portion.

17. The device according to claim 1, wherein the first insulting portion and the second insulating portion are provided to be separated from each other in the second direction.

18. The device according to claim 17, wherein the first insulating portion is provided to be separated from the second insulating portion, and
a position of the first insulting portion along a third direction perpendicular to the first direction and the second direction is different from a position of the second insulting portion along the third direction.

19. The device according to claim 18, wherein, as viewed in the second direction, a part of the first insulating portion overlaps with a part of the second insulting portion.

20. The device according to claim 17, wherein
a plurality of the first electrode portions are provided in the third direction at a first pitch, and
a plurality of the second electrode portions are provided in the third direction at a second pitch greater than the first pitch.
